(19) United States
(12) Patent Application Publication
(10) Pub. No.: US 2019/0237361 A1
(43) Pub. Date: Aug. 1, 2019

(54) SEMICONDUCTOR DEVICE AND MANUFACTURING METHOD OF SEMICONDUCTOR DEVICE

(71) Applicant: RENESAS ELECTRONICS CORPORATION, Tokyo (JP)

(72) Inventor: Tatsuya USAMI, Ibaraki (JP)

(21) Appl. No.: 16/242,686

(22) Filed: Jan. 8, 2019

(30) Foreign Application Priority Data
Feb. 1, 2018 (JP) 2018-016772

(51) Int. Cl. H01L 21/768; H01L 23/522; H01L 23/532

(52) U.S. Cl. CPC H01L 21/76816; H01L 23/5226; H01L 21/76885; H01L 21/76883; H01L 21/76843; H01L 21/32135; H01L 23/53266; H01L 23/53295; H01L 23/53209; H01L 21/76835; H01L 23/53223

(57) ABSTRACT

In a semiconductor device, among first wirings, second wirings and a third wiring formed in the same wiring layer, the first wirings having small wiring width are each composed of a stacked film of a first barrier conductor film, a first conductor film made of a material mainly containing a metal element whose mean free path of electrons is smaller than that of copper, and a second barrier conductor film. Also, among the first wirings, the second wirings and the third wiring formed in the same wiring layer, the second wirings and the third wiring having large wiring width are each composed of a stacked film of a third barrier conductor film and a second conductor film made of copper.

### CROSS-REFERENCE TO RELATED APPLICATION

The present application claims priority from Japanese Patent Application No. 2018-016772 filed on Feb. 1, 2018, the content of which is hereby incorporated by reference into this application.

### TECHNICAL FIELD OF THE INVENTION

The present invention relates to a semiconductor device and a manufacturing method thereof, and can be suitably applicable to a semiconductor device having a fine wiring structure and a manufacturing method thereof.

### BACKGROUND OF THE INVENTION

In a semiconductor device, various wirings are formed for the supply of power supply potential and the transmission of signals. The wirings have different widths in accordance with their purposes, and the material thereof is selected as appropriate.

For example, T. Nogami et al., “Cobalt/Copper Composite Interconnects for Line Resistance Reduction in both Fine and Wide Lines” Proc. IITC 12.2, 2017 (Non-Patent Document 1) describes a method of forming wirings having different widths in the same wiring layer by using both cobalt and copper.

### SUMMARY OF THE INVENTION

The inventor of the present invention has been studying the reduction of wiring resistance in a semiconductor device in which wirings having different wiring widths are formed in the same wiring layer and a manufacturing method thereof.

It is desired to improve the performance of the semiconductor device by devising the semiconductor device and the manufacturing method thereof.

Other problems and novel features of the present invention will be apparent from the description of the present specification and the accompanying drawings.

In a semiconductor device according to an embodiment, among wirings formed in the same wiring layer, a wiring having small wiring width is composed of a first barrier conductor film and a first conductor film made of a material mainly containing a metal element whose mean free path of electrons is smaller than that of copper. Also, among the wirings formed in the same wiring layer, a wiring having large wiring width is composed of a second barrier conductor film and a second conductor film made of copper.

According to the embodiment, it is possible to improve the performance of the semiconductor device.

### BRIEF DESCRIPTIONS OF THE DRAWINGS

FIG. 1 is a cross-sectional view of a principal part of a semiconductor device according to an embodiment;

FIG. 2 is a cross-sectional view of a principal part showing a manufacturing process of the semiconductor device according to the embodiment;

FIG. 3 is a cross-sectional view of a principal part in the manufacturing process of the semiconductor device continued from FIG. 2;

FIG. 4 is a cross-sectional view of a principal part in the manufacturing process of the semiconductor device continued from FIG. 3;

FIG. 5 is a cross-sectional view of a principal part in the manufacturing process of the semiconductor device continued from FIG. 4;

FIG. 6 is a cross-sectional view of a principal part in the manufacturing process of the semiconductor device continued from FIG. 5;

FIG. 7 is a cross-sectional view of a principal part in the manufacturing process of the semiconductor device continued from FIG. 6;

FIG. 8 is a cross-sectional view of a principal part in the manufacturing process of the semiconductor device continued from FIG. 7;

FIG. 9 is a cross-sectional view of a principal part in the manufacturing process of the semiconductor device continued from FIG. 8;

FIG. 10 is a cross-sectional view of a principal part in the manufacturing process of the semiconductor device continued from FIG. 9;

FIG. 11 is a cross-sectional view of a principal part in the manufacturing process of the semiconductor device continued from FIG. 10;

FIG. 12 is a cross-sectional view of a principal part in the manufacturing process of the semiconductor device continued from FIG. 11;

FIG. 13 is a cross-sectional view of a principal part in the manufacturing process of the semiconductor device continued from FIG. 12;

FIG. 14 is a cross-sectional view of a principal part in the manufacturing process of the semiconductor device continued from FIG. 13;

FIG. 15 is a cross-sectional view of a principal part in the manufacturing process of the semiconductor device continued from FIG. 14;

FIG. 16 is a cross-sectional view of a principal part of a semiconductor device according to a studied example;

FIG. 17 is a cross-sectional view of a principal part showing a manufacturing process of the semiconductor device according to the studied example;

FIG. 18 is a cross-sectional view of a principal part showing the manufacturing process of the semiconductor device continued from FIG. 17;

FIG. 19 is a cross-sectional view of a principal part showing the manufacturing process of the semiconductor device continued from FIG. 18;

FIG. 20 is a cross-sectional view of a principal part showing the manufacturing process of the semiconductor device continued from FIG. 19;

FIG. 21 is a cross-sectional view of a principal part showing the manufacturing process of the semiconductor device continued from FIG. 20;

FIG. 22 is a cross-sectional view of a principal part of a semiconductor device according to a first modification;

FIG. 23 is a cross-sectional view of a principal part of a semiconductor device according to a second modification;

FIG. 24 is a cross-sectional view of a principal part of a semiconductor device according to a third modification;

FIG. 25 is a cross-sectional view of a principal part of a semiconductor device according to a second embodiment;

FIG. 26 is a cross-sectional view of a principal part showing a manufacturing process of the semiconductor device according to the second embodiment;

FIG. 27 is a cross-sectional view of a principal part showing the manufacturing process of the semiconductor device continued from FIG. 26;

FIG. 28 is a cross-sectional view of a principal part showing the manufacturing process of the semiconductor device continued from FIG. 27;

FIG. 29 is a cross-sectional view of a principal part showing the manufacturing process of the semiconductor device continued from FIG. 28;

FIG. 30 is a cross-sectional view of a principal part showing the manufacturing process of the semiconductor device continued from FIG. 29;

FIG. 31 is a plan view of a semiconductor device according to a third embodiment;

FIG. 32 is a view seen along a direction of arrows A-A in FIG. 31;

FIG. 33 is a cross-sectional view showing a structure taken along a line B-B in FIG. 31;

FIG. 34 is a cross-sectional view of a principal part showing a manufacturing process of a semiconductor device according to the third second embodiment;

FIG. 35 is a cross-sectional view of a principal part showing the manufacturing process of the semiconductor device continued from FIG. 34;

FIG. 36 is a cross-sectional view of a principal part showing the manufacturing process of the semiconductor device continued from FIG. 35;

FIG. 37 is a cross-sectional view of a principal part showing the manufacturing process of the semiconductor device continued from FIG. 36;

FIG. 38 is a cross-sectional view of a principal part showing the manufacturing process of the semiconductor device continued from FIG. 37;

FIG. 39 is a cross-sectional view of a principal part showing the manufacturing process of the semiconductor device continued from FIG. 38;

FIG. 40 is a cross-sectional view of a principal part showing the manufacturing process of the semiconductor device continued from FIG. 39; and

FIG. 41 is a cross-sectional view of a principal part showing the manufacturing process of the semiconductor device continued from FIG. 40.

### DESCRIPTIONS OF THE PREFERRED EMBODIMENTS

### Explanation of Description Form, Basic Terminology and Usage in Present Application

In the present application, the embodiments will be described in a plurality of sections or the like when required as a matter of convenience. However, these sections or the like are not irrelevant to each other unless otherwise stated, and a part of one example relates to the other example as details or a part or the entire of a modification example regardless of the order of description. Also, the repetitive description of similar parts will be omitted in principle. Further, the constituent elements in the embodiments are not always indispensable unless otherwise stated or except for the case where the constituent elements are theoretically indispensable in principle or the constituent elements are obviously indispensable from the context.

Likewise, in the description of the embodiments, the phrase “X made of A” for a material, a composition or the like is not intended to exclude those containing elements other than A unless otherwise specified and except for the case where it clearly contains only A from the context. For example, as for a component, it means “X containing A as a main component”. For example, a “silicon member” or the like is not limited to pure silicon and it is obvious that the silicon member includes a member made of silicon germanium (SiGe) alloy, a member made of multicomponent alloy containing silicon as a main component, and a member containing other additives or the like. In addition, gold plating, a Cu layer, nickel plating or the like includes a member containing gold, Cu, nickel or the like as a main component as well as a pure one unless otherwise specified clearly.

In addition, when referring to a specific value or amount, a value or amount larger or smaller than the specific value or amount is also applicable unless otherwise stated or except for the case where the value or amount is logically limited to the specific value or amount and the value or amount is apparently limited to the specific value or amount from the context.

Further, in the drawings for the embodiments, the same or similar parts are denoted by the same or similar reference character or reference number, and the descriptions thereof are not repeated in principle.

In addition, in the attached drawings, hatching may be omitted even in cross-sections in the case where the hatchings make the drawings complicated on the contrary or discrimination from void is clear. In relation to this, when it is clear from the description or the like, an outline of a background may be omitted even in a planarly closed hole. Furthermore, even in the cases other than the cross-section, hatching may be applied so as to clarify that a portion is not a vacant space.

### First Embodiment

<Configuration of Semiconductor Device>

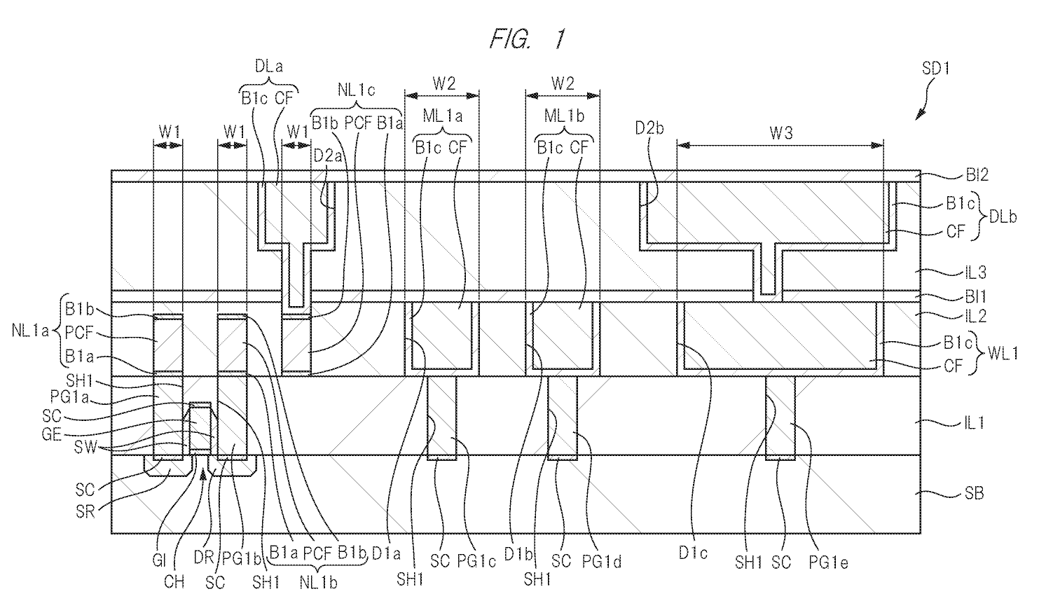

A configuration of a semiconductor device according to an embodiment will be described with reference to FIG. 1. FIG. 1 is a cross-sectional view of a principal part of a semiconductor device SD1 according to the first embodiment.

As shown in FIG. 1, the semiconductor device SD1 according to the present embodiment includes a substrate (semiconductor substrate) SB. The substrate SB is made of, for example, silicon (Si). A MOSFET (Metal-Oxide-Semiconductor Field-Effect Transistor) is formed on a main surface of the substrate SB. The MOSFET formed in the semiconductor device SD1 includes a source region SR and a drain region DR formed in the substrate SB, a channel region CH formed between the source region SR and the drain region DR, a gate insulating film GI formed on the channel region CH, a gate electrode GE formed on the gate insulating film GI, and a sidewall spacer SW formed so as to cover a side wall of the gate electrode GE. A silicide layer SC is formed on each front surface of the gate electrode GE, the source region SR, and the drain region DR. The gate insulating film GI is made of, for example, a silicon oxide film, and the gate electrode GE is made of, for example, a polysilicon film.

In addition, the semiconductor device SD1 according to the present embodiment includes an insulating layer IL1 formed on the substrate SB so as to cover the semiconductor element (MOSFET) described above. The insulating layer IL1 is made of, for example, a silicon oxide film. A plurality of through holes SH1 are formed in the insulating layer IL1, and conductive plugs PG1a, PG1b, PG1c, PG1d, and PG1e are buried in the through holes SH1. Among the plurality of plugs PG1a, PG1b, PG1c, PG1d, and PG1e, the plug PG1a is arranged on the source region SR of the MOSFET via the silicide layer SC, and the plug PG1b is arranged on the drain region DR of the MOSFET via the silicide layer SC. Though not shown, for example, the other plugs PG1c, PG1d, and PG1e are wirings for the connection to the element formed on the substrate SB, and the plugs PG1c, PG1d, and PG1e are also arranged on the silicide layer SC formed on the substrate SB. The silicide layer SC makes it possible to reduce the contact resistance between, for example, the plug PG1a (plug PG1b) and the source region SR (drain region DR) of the MOSFET described above.

The plugs PG1a, PG1b, PG1c, PG1d, and PG1e are each composed of a barrier conductor film that covers a side wall and a bottom surface of the through hole SH1 and a main conductor film completely buried in the through hole SH1 via the barrier conductor film. The barrier conductor film is made of, for example, a titanium (Ti) film, a tantalum (Ta) film, a titanium nitride (TiN) film or a tantalum nitride (TaN) film, and these materials can be selected as appropriate based on diffusion prevention (barrier) properties with respect to the metal constituting the main conductor film of the wiring and characteristics (electrical resistivity or the like) as the wiring. Further, the main conductor film is made of, for example, tungsten (W).

Wirings NL1a, NL1b, and NL1c are formed on the insulating layer IL1. The wirings NL1a, NL1b, and NL1c are each composed of a stacked film of a barrier conductor film B1a, a conductor film PCF, and a barrier conductor film B1b. Note that the barrier conductor films B1a and B1b are not formed on side surfaces of the wirings NL1a, NL1b, and NL1c.

The conductor film PCF is made of a material mainly containing a metal element whose mean free path of electrons is smaller than that of copper (Cu) or a material mainly containing alloy of such metal elements. Herein, the mean free path of electrons means an average value of distances over which electrons traveling in semiconductor or metal can proceed without being disturbed by scattering (collision) due to atoms. Specifically, the conductor film PCF is made of a material mainly containing any of cobalt (Co), tungsten (W), ruthenium (Ru), molybdenum (Mo), aluminum (Al), nickel (Ni), rhodium (Rh), iridium (Ir), zinc (Zn), cobalt ruthenium (CoRu), and cobalt aluminum (CoAl).

The barrier conductor films B1a and B1b are made of, for example, a tantalum nitride (TaN) film, a titanium nitride (TiN) film, or a stacked film of a tantalum nitride (TaN) film and a tantalum (Ta) film.

In addition, an insulating layer IL2 is formed on the insulating layer IL1 so as to cover the wirings NL1a, NL1b, and NL1c. The insulating layer IL2 is made of a material having a relative permittivity lower than that of silicon oxide, that is, a low-k material such as a porous MSQ (Methyl Silsesquioxane) film, a silicon oxycarbide (SiOC) film, or a porous silicon oxycarbide film.

In addition, wirings ML1a and ML1b and a wiring WL1 are formed in the insulating layer IL2. The wirings ML1a and ML1b are buried in wiring trenches D1a and D1b formed in the insulating layer IL2, respectively. The wiring WL1 is buried in a wiring trench D1c formed in the insulating layer IL2. The wirings ML1a and ML1b and the wiring WL1 are damascene wirings (damascene buried wirings) formed by the damascene method. In particular, the wirings ML1a and ML1b and the wiring WL1 are single damascene wirings formed by the single damascene method. The single damascene method is a method in which a wiring trench is formed in an upper surface of an interlayer insulating film, and metal is buried in the wiring trench, thereby forming a wiring in the wiring trench.

The wirings NL1a, NL1b, and NL1c, the wirings ML1a and ML1b, and the wiring WL1 are all formed in the insulating layer IL2. Also, a width W1 of each of the wirings NL1a, NL1b, and NL1c is smaller (thinner, narrower) than a width W2 of each of the wirings ML1a and ML1b. In addition, the width W2 of each of the wirings ML1a and ML1b is smaller (thinner, narrower) than a width W3 of the wiring WL1. Namely, the wirings NL1a, NL1b, and NL1c, the wirings ML1a and ML1b, and the wiring WL1 having different wiring widths are formed in the same layer (same wiring layer).

The wirings ML1a and ML1b and the wiring WL1 are each composed of a stacked film of a barrier conductor film Mc and a conductor film CF. The conductor film CF is made of copper (Cu). The barrier conductor film Mc is composed of, for example, a tantalum nitride (TaN) film, a titanium nitride (TiN) film, or a stacked film of a tantalum nitride (TaN) film and a tantalum (Ta) film.

Note that the plug PG1a is arranged between the wiring NL1a and the source region SR of the MOSFET to electrically connect the wiring NL1a and the source region SR. The plug PG1b is arranged between the wiring NL1b and the drain region DR of the MOSFET to electrically connect the wiring NL1b and the drain region DR. The plug PG1c is arranged between, for example, the wiring ML1a and an element (not shown) to electrically connect the wiring ML1a and the element. The plug PG1d is arranged between, for example, the wiring ML1b and an element (not shown) to electrically connect the wiring ML1b and the element. The plug PG1e is arranged between, for example, the wiring WL1 and an element (not shown) to electrically connect the wiring WL1 and the element.

Also, a barrier insulating film BI1 is formed on the insulating layer IL2. Thus, upper surfaces of the wirings ML1a and ML1b and the wiring WL1 are covered with the barrier insulating film BI1. The barrier insulating film BI1 is an insulating film for preventing the diffusion of copper contained in the conductor film CF, and is made of, for example, a silicon carbonitride (SiCN) film, a silicon oxynitride (SiON) film, a PSG (Phosphorous Silicate Glass) film or a silicon nitride (Si₃N₄) film.

Further, an insulating layer IL3 is formed on the barrier insulating film BI1. The insulating layer IL3 is made of a material having a relative permittivity lower than that of silicon oxide, that is, a low-k material such as a hydrogenated silicon oxycarbide (SiCOH) film, a silicon oxycarbide (SiOC) film, or a porous SiOC film.

Wirings DLa and DLb are formed in the insulating layer IL3. The wirings DLa and DLb are buried in wiring trenches D2a and D2b formed in the insulating layer IL3, respectively. The wirings DLa and DLb are damascene wirings (damascene buried wirings) formed by the damascene method. In particular, the wirings DLa and DLb are dual damascene wirings formed by the dual damascene method. The dual damascene method is a method in which, after a via hole penetrating an interlayer insulating film is formed and a wiring trench shallower than the via hole is formed in an upper surface of the interlayer insulating film, metal is buried in the via hole and the wiring trench, thereby forming a via in the via hole and a wiring in the wiring trench thereon at the same time.

The wiring DLa penetrates the barrier insulating film BI1 and is electrically connected to the wiring NL1c. The wiring DLb penetrates the barrier insulating film BI1 and is electrically connected to the wiring WL1.

Also, a barrier insulating film BI2 is formed on the insulating layer IL3. Thus, upper surfaces of the wirings DLa and DLb are covered with the barrier insulating film BI2.

Though not particularly shown, another wiring layer may be formed in an upper layer of the barrier insulating film BI2, and a pad electrode and a passivation film may be formed in a further upper layer.

The width W1 of each of the wirings NL1a, NL1b, and NL1c is, for example, 10 to 15 nm. The width W2 of each of the wirings ML1a and ML1b is, for example, 15 to 50 nm. The width W3 of the wiring WL1 is, for example, 50 to 100 nm. A film thickness of each of the barrier conductor films B1a and B1b is, for example, 1 to 3 nm, and a film thickness of the barrier conductor film B1c is, for example, 3 to 5 nm. A film thickness of the conductor film PCF is, for example, 30 to 60 nm, and a film thickness of the conductor film CF is, for example, 50 to 80 nm. A thickness of the insulating layer IL1 is, for example, 50 to 100 nm, a thickness of the insulating layer IL2 is, for example, 60 to 90 nm, and a thickness of the insulating layer IL3 is, for example, 100 to 300 nm. A film thickness of the barrier insulating film BI1 is, for example, 5 to 10 nm and a film thickness of the barrier insulating film BI2 is, for example, 5 to 10 nm.

In the semiconductor device SD1 according to the present embodiment, the case where the wirings NL1a, NL1b, and NL1c, the wirings ML1a and ML1b, and the wiring WL1 constitute the lowermost wiring layer and the MOSFET and the plurality of plugs PG1a, PG1b, PG1c, PG1d, and PG1e are formed as the structure below the insulating layer IL2 has been described as an example, but the semiconductor device SD1 is not limited to this.

Note that the case where the MOSFET is a so-called planar type MOSFET having the channel configured two-dimensionally has been described as an example, but the MOSFET is not limited to this. For example, the MOSFET may be a so-called Fin-FET in which a silicon surface is formed into a fin shape and a channel is configured three-dimensionally or a so-called silicon-nanowire FET in which the channel is formed into a cylindrical shape to form a nanowire and a periphery of the nanowire is surrounded by the gate electrode.

<Manufacturing Method of Semiconductor Device>

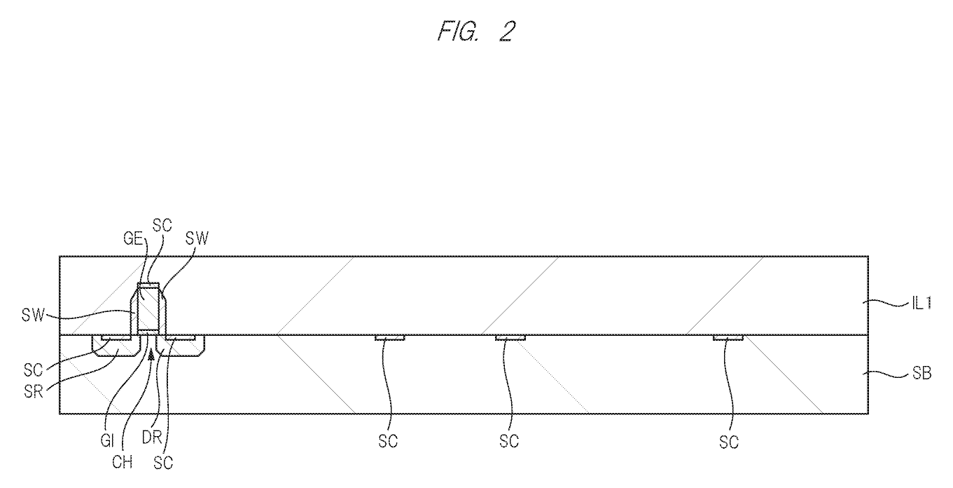

A manufacturing method of the semiconductor device SD1 according to the present embodiment will be described in order of processes with reference to FIGS. 2 to 15. FIGS. 2 to 15 are cross-sectional views of a principal part in the manufacturing process of the semiconductor device SD1 according to the present embodiment, and each show the cross-section corresponding to FIG. 1 shown above.

First, as shown in FIG. 2, the substrate SB is prepared. As the substrate SB, for example, a silicon wafer is used. After forming a silicon oxide film by thermally oxidizing a MOSFET formation region (active region) of the substrate SB, for example, a polysilicon film is formed on the active region. Then, the polysilicon film and the silicon oxide film are patterned by the photolithography technique, the dry etching technique, and the like to form the gate electrode GE and the gate insulating film GI of the MOSFET. Further, a p-type (or n-type) impurity (dopant) is ion-implanted into the substrate SB by self-alignment using the gate electrode GE as a mask. Thereafter, the impurity is diffused by heat treatment to form the source region SR and the drain region DR of the MOSFET in the substrate SB.

Next, after forming the sidewall spacer SW on the side wall of the gate electrode GE, the salicide (Self-Aligned Silicide) process in which a cobalt film is deposited and heat-treated is performed, thereby forming the silicide layer SC on a part of the front surface of the substrate SB including a part of each front surface of the gate electrode GE, the source region SR, and the drain region DR. The silicide layer SC is made of, for example, a metal silicide film such as a cobalt silicide film.

Next, the insulating layer IL1 made of, for example, a silicon oxide film is formed on the substrate SB by, for example, the CVD (Chemical Vapor Deposition) method.

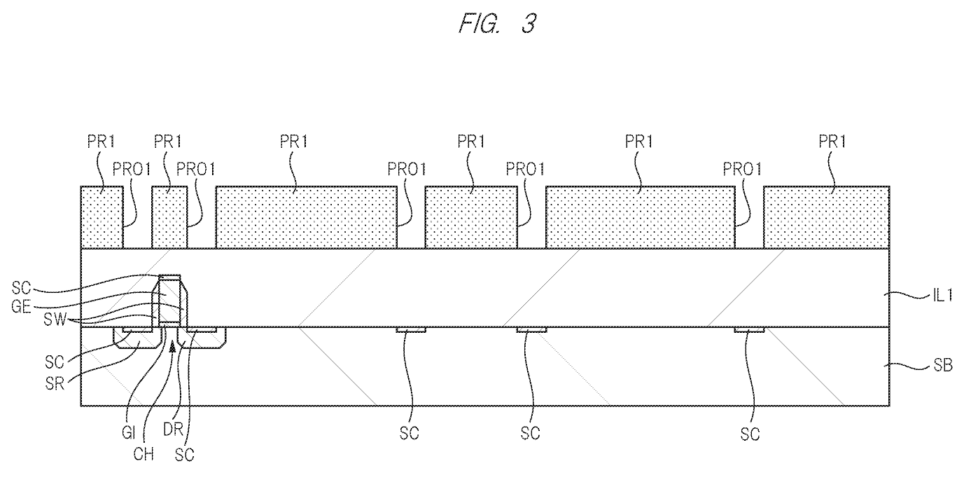

Next, as shown in FIG. 3, a photoresist film PR1 is formed on the insulating layer IL1. Then, the photoresist film PR1 is patterned (exposed and developed) to form openings PRO1 in the photoresist film PR1.

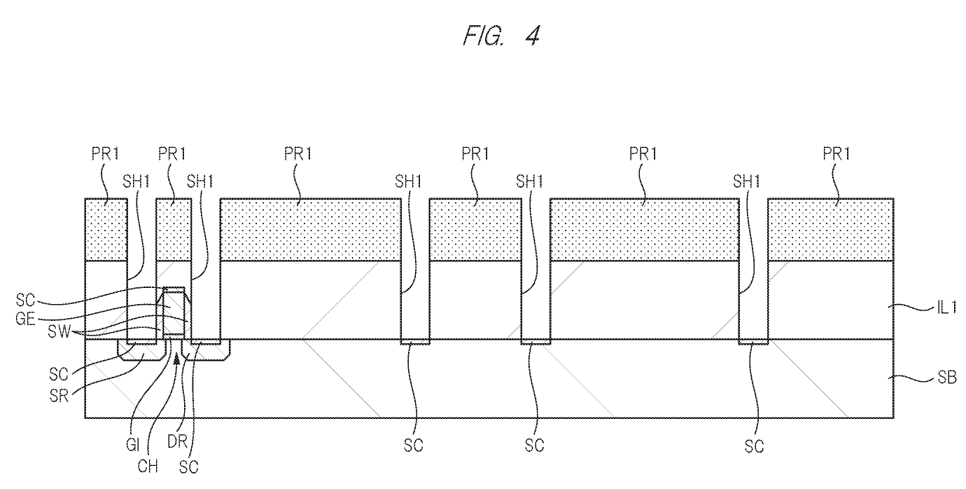

Next, as shown in FIG. 4, the insulating layer IL1 is subjected to dry etching (anisotropic etching) through the openings PRO1 of the photoresist film PR1 with using the photoresist film PR1 as a mask, thereby patterning the insulating layer IL1. Thus, the through holes SH1 are formed in the insulating layer IL1. The through holes SH1 are formed such that the silicide layers SC formed on a part of the front surface of the substrate SB including a part of each front surface of the source region SR and the drain region DR are exposed. Thereafter, the photoresist film PR1 is removed by the etching using organic solvent containing organic acid or the oxygen asking.

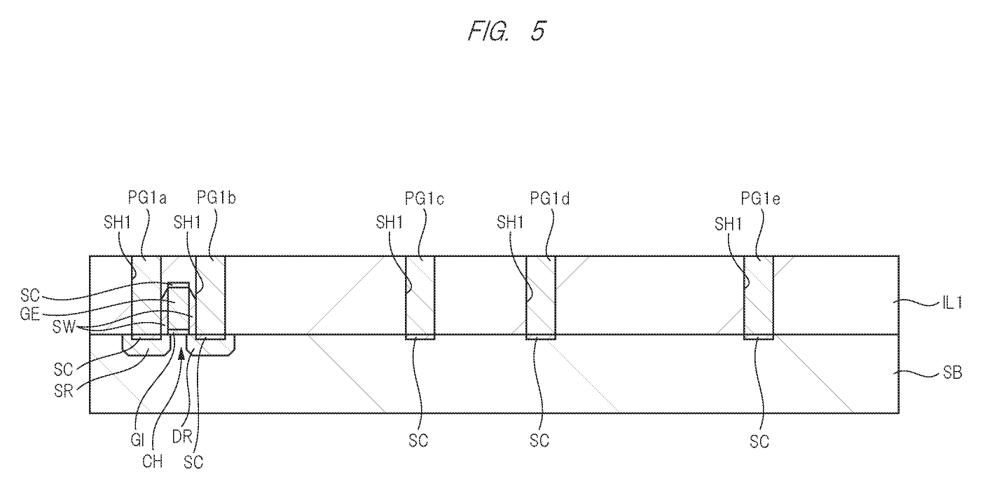

Next, as shown in FIG. 5, a tungsten film is buried in the through holes SH1 in the insulating layer IL1 to form the plugs PG1a, PG1b, PG1c, PG1d, and PG1e.

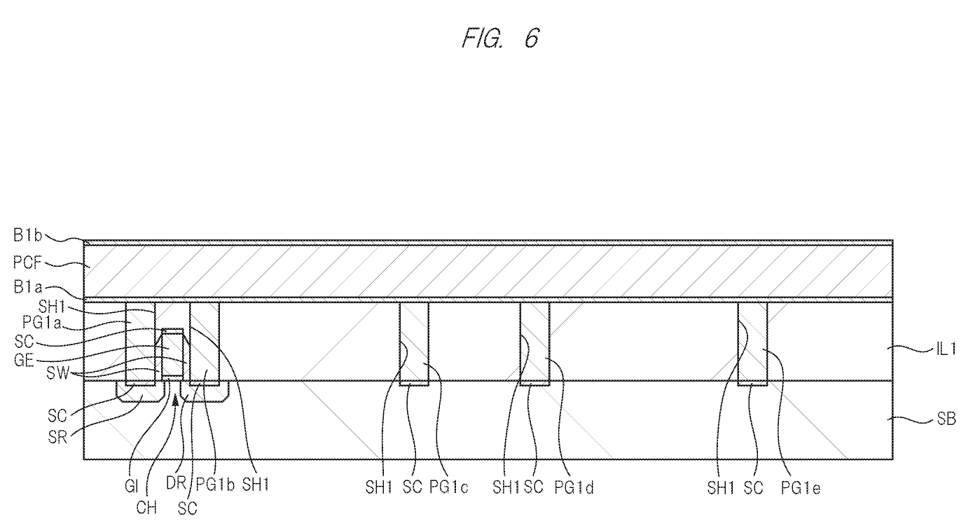

Next, as shown in FIG. 6, the barrier conductor film B1a made of, for example, tantalum nitride is formed on the insulating layer IL1 by, for example, the PVD (Physical Vapor Deposition) method. Next, the conductor film PCF made of, for example, cobalt is formed on the barrier conductor film B1a by, for example, the PVD method. Then, the barrier conductor film B1b made of, for example, tantalum nitride is formed on the conductor film PCF by, for example, the PVD method.

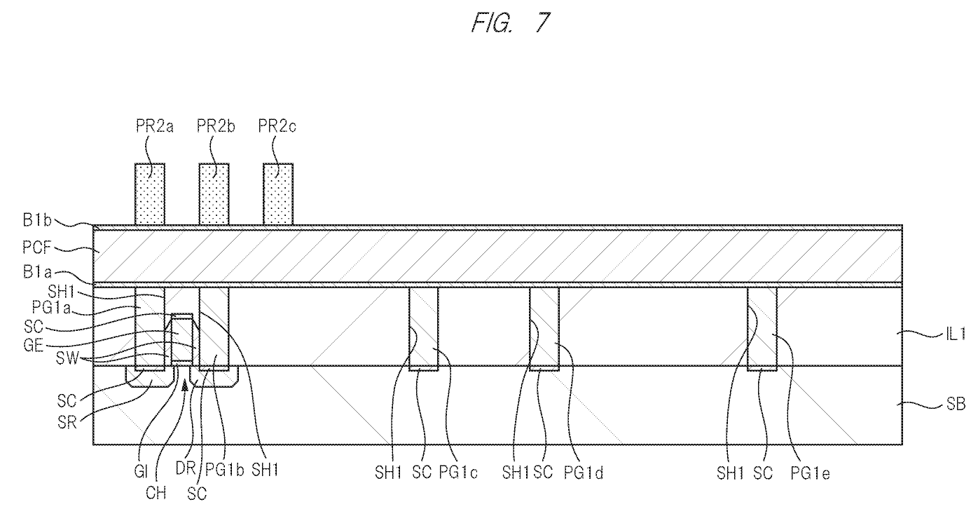

Next, as shown in FIG. 7, a photoresist film is formed on the barrier conductor film B1b, and the photoresist film is patterned to form photoresist films PR2a, PR2b, and PR2c.

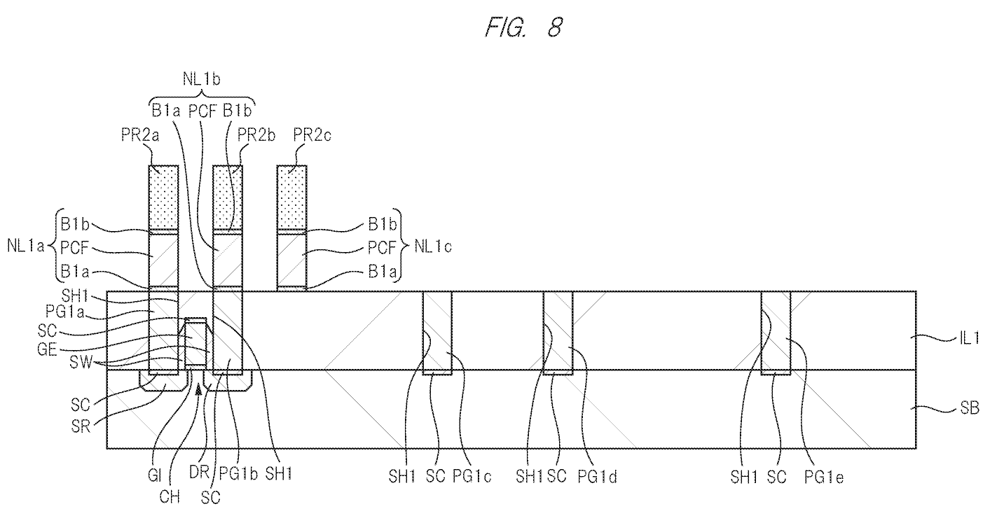

Next, as shown in FIG. 8, the barrier conductor film B1a, the conductor film PCF, and the barrier conductor film B1b are patterned by the dry etching (anisotropic etching) using fluorine gas at about 200 to 300° C., with using the photoresist films PR2a, PR2b, and PR2C as a mask. Note that the barrier conductor film B1a, the conductor film PCF, and the barrier conductor film B1b may be patterned by the dry etching using mixed gas of halogen gas and oxidizing gas.

Alternatively, the barrier conductor film B1a, the conductor film PCF, and the barrier conductor film B1b may be patterned by a multi-patterning method such as the LELE (Litho-Etch-Litho-Etch) in which fine processing is performed in two patterning steps or the SADP (Self-Aligned Double Patterning) in which fine processing is performed using dummy patterns.

Thereafter, the photoresist films PR2a, PR2b, and PR2C are removed by the etching using organic solvent containing organic acid or the oxygen plasma asking. Thus, the wirings NL1a, NL1b, and NL1c each composed of a stacked film of the barrier conductor film B1a, the conductor film PCF, and the barrier conductor film B1b are formed on the insulating layer IL1.

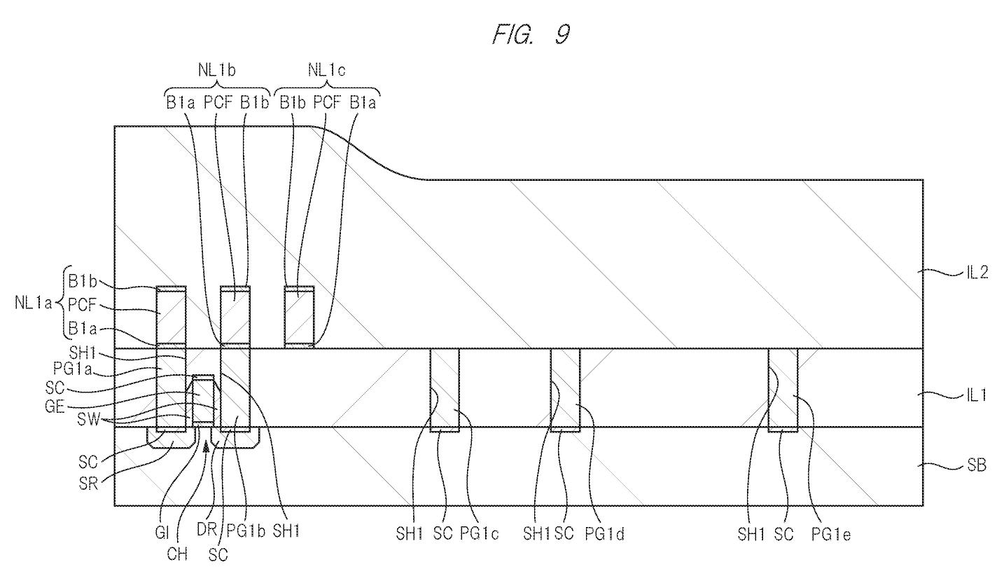

Next, as shown in FIG. 9, for example, MSQ is coated to 100 to 200 nm, and then sintered at 400° C. for 30 minutes to form the insulating layer IL2 on the insulating layer IL1 so as to cover the wirings NL1a, NL1b, and NL1c. Note that the insulating layer IL2 made of, for example, a silicon oxycarbide (SiOC) film or a porous SiOC film may be formed by, for example, the PECVD (Plasma-Enhanced Chemical Vapor Deposition) method instead of coating the MSQ. Thereafter, the insulating layer IL2 is planarized by the CMP (Chemical Mechanical Polishing) method such that the insulating layer IL2 has a thickness of 60 to 90 nm.

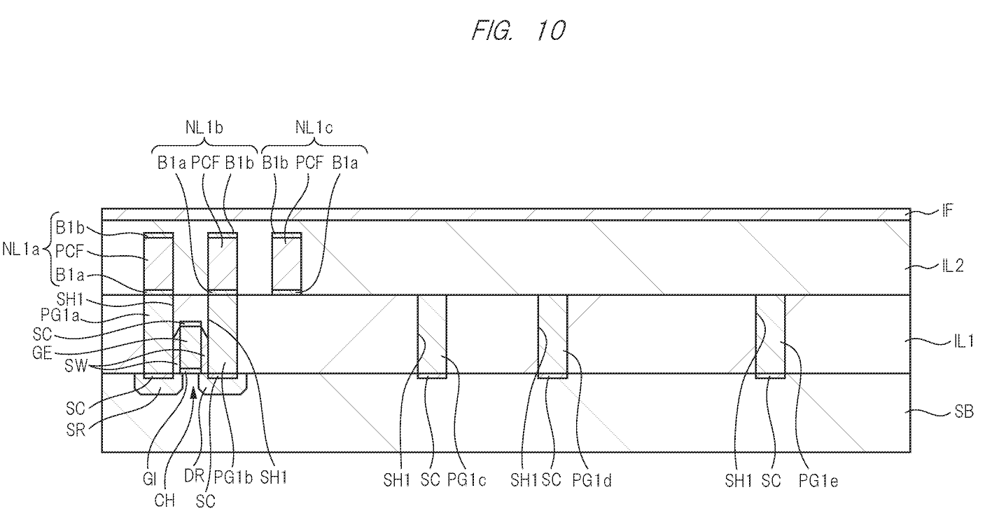

Next, as shown in FIG. 10, the insulating film IF made of, for example, a silicon oxide film is formed on the insulating layer IL2 by, for example, the PECVD method. The insulating film IF functions as a protective film for the insulating layer IL2 in the following process.

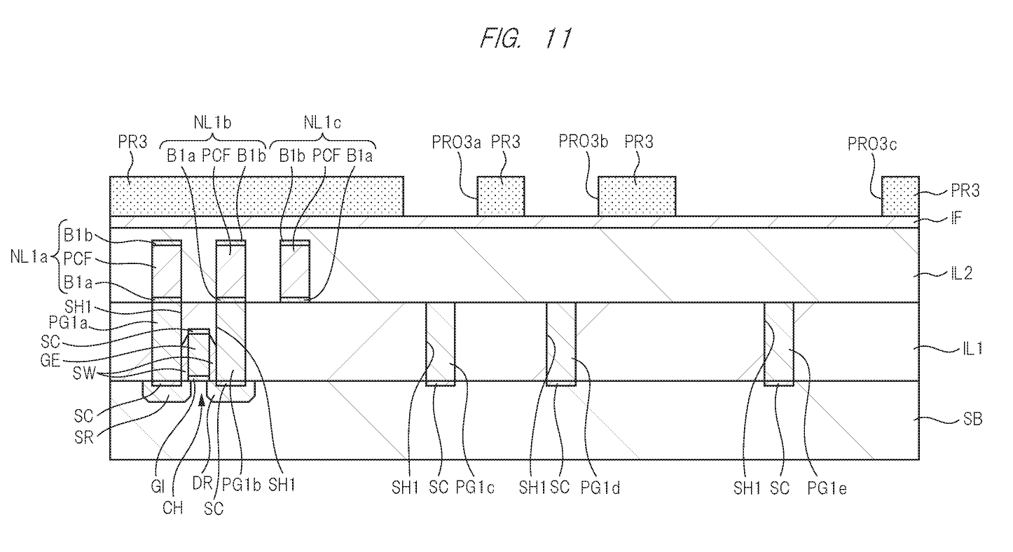

Next, as shown in FIG. 11, a photoresist film PR3 is formed on the insulating film IF. Then, the photoresist film PR3 is patterned to form openings PRO3a, PRO3b, and PRO3c in the photoresist film PR3.

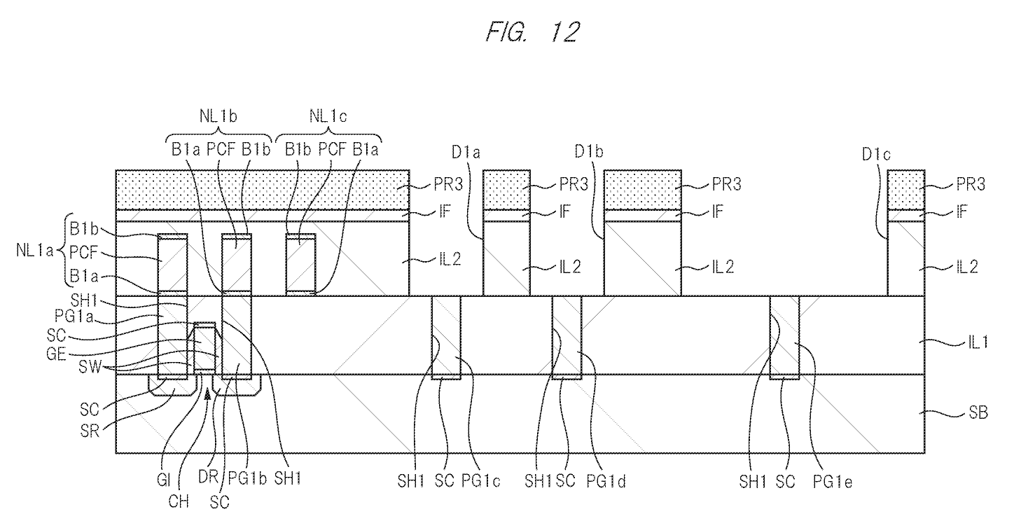

Next, as shown in FIG. 12, the insulating film IF and the insulating layer IL2 are subjected to dry etching (anisotropic etching) by the RIE (Reactive Ion Etching) method using fluorocarbon gas through the openings PRO3a, PRO3b, and PRO3c of the photoresist film PR3 with using the photoresist film PR3 as a mask, thereby patterning the insulating layer IL2. Thus, the wiring trenches D1a, D1b, and D1c are formed in the insulating layer IL2. The wiring trenches D1a, D1b, and D1c are formed such that a part of the upper surface of the insulating layer IL1 including each upper surface of the plugs PG1c, PG1d, and PG1e is exposed. Thereafter, the photoresist film PR3 is removed by the etching using organic solvent containing organic acid or the oxygen asking.

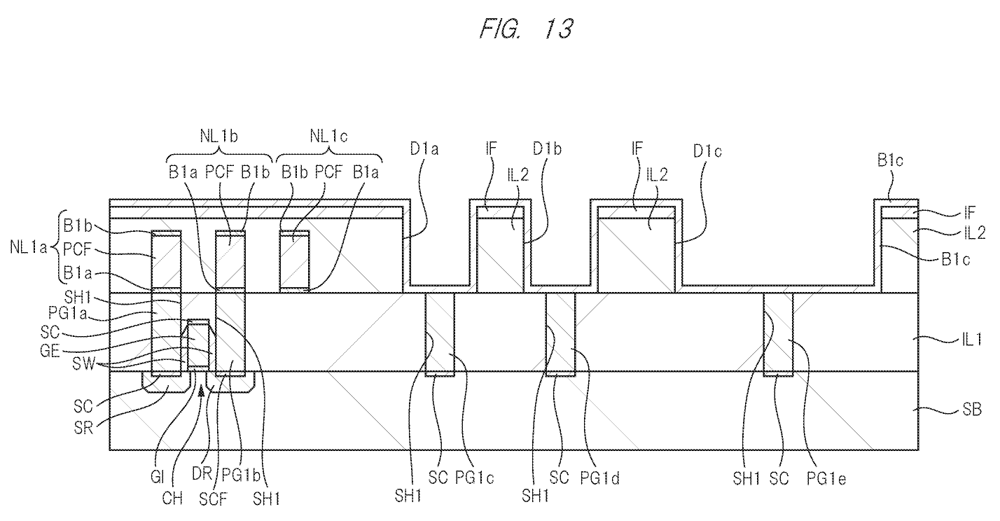

Next, as shown in FIG. 13, the barrier conductor film B1c made of, for example, tantalum nitride is formed on the insulating layer IL2 by, for example, the PVD method. Thus, the barrier conductor film B1c is formed on the bottoms and side walls of the wiring trenches D1a, D1b, and D1c.

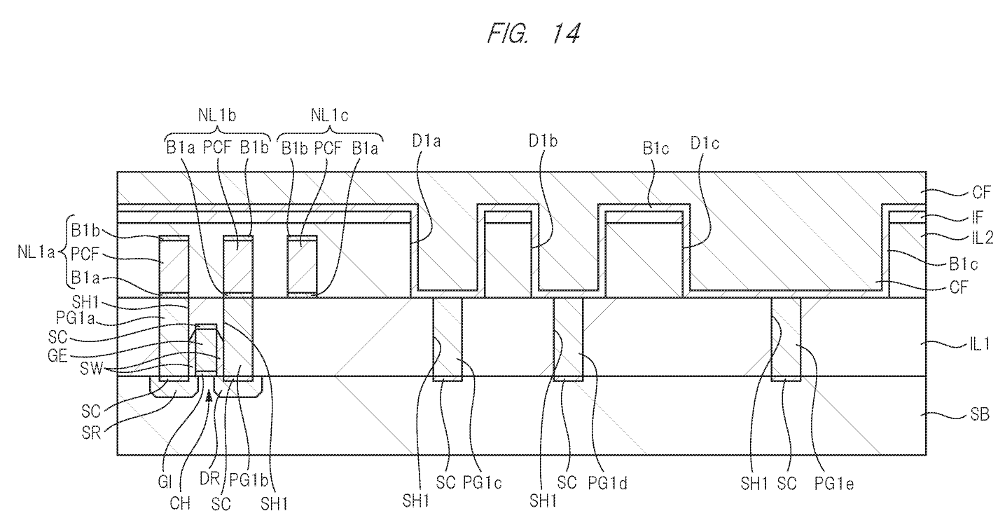

Next, though not shown, a seed film made of copper having a thickness of 30 to 50 nm is formed on the barrier conductor film B1c by, for example, the PVD method. Then, as shown in FIG. 14, the conductor film CF made of copper having a thickness of 100 to 200 nm is formed on the seed film (not shown) by the electroplating method. Thus, the wiring trenches D1a, D1b, and D1c are filled with the conductor film CF. Thereafter, the heat treatment is performed at about 450° C. for 30 minutes. This heat treatment enables the removal of the moisture in the conductor film CF and the coarsening of crystal grains by recrystallization of copper in the conductor film CF.

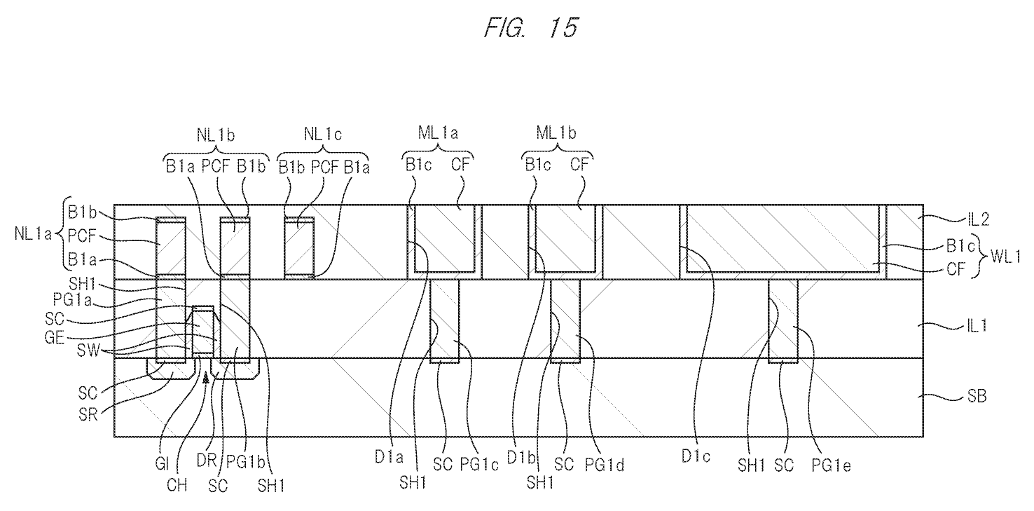

Next, as shown in FIG. 15, the barrier conductor film B1c and the conductor film CF outside the wiring trenches D1a, D1b, and D1c are removed by the CMP method. Thus, the barrier conductor film B1c and the conductor film CF are left in the wiring trenches D1a, D1b, and D1c. As a result, the wirings ML1a and ML1b and the wiring WL1 each made of the barrier conductor film B1c and the conductor film CF are formed on the insulating layer IL1. Note that the insulating film IF is also removed together with the barrier conductor film B1c and the conductor film CF outside the wiring trenches D1a, D1b, and D1c in order to reduce the capacitance between wirings.

Next, as shown in FIG. 1, the barrier insulating film BI1 is formed on the insulating layer IL2 by, for example, the PECVD method. Thus, the wirings ML1a and ML1b and the wiring WL1 are covered with the barrier insulating film BI1 made of a silicon carbonitride (SiCN) film.

Next, the insulating layer IL3 made of a porous hydrogenated silicon oxycarbide (SiCOH) film is formed by, for example, the CVD method on the barrier insulating film BI1.

Next, a photoresist film (not shown) is formed on the insulating layer IL3, and the insulating layer IL3 is subjected to the dry etching (anisotropic etching) with using the photoresist film as a mask, thereby patterning the insulating layer IL3. Thus, the wiring trenches D2a and D2b are formed in the insulating layer IL3. The wiring trench D2a penetrates the insulating layer IL3, the barrier insulating film BI1, and the insulating layer IL2 and forms an opening on the upper surface of the barrier conductor film B1b constituting the wiring NL1c. Also, the wiring trench D2b penetrates the insulating layer IL3, the barrier insulating film BI1, and the insulating layer IL2 and forms an opening on the upper surface of the conductor film CF constituting the wiring WL1.

Next, the barrier conductor film B1c made of, for example, tantalum nitride is formed on the insulating layer IL3 by, for example, the PVD method. Next, though not shown, a seed film made of copper having a thickness of 30 to 50 nm is formed on the barrier conductor film B1c by, for example, the PVD method. Then, the conductor film CF made of copper having a thickness of 100 to 200 nm is formed on the seed film (not shown) by the electroplating method. Thereafter, the heat treatment is performed at about 450° C. for 30 minutes.

Next, the barrier conductor film B1c and the conductor film CF outside the wiring trenches D2a and D2b are removed by the CMP method. Thus, the barrier conductor film B1c and the conductor film CF are left in the wiring trenches D2a and D2b. As a result, the wirings DLa and DLb each made of the barrier conductor film B1c and the conductor film CF are formed. The wiring DLa is electrically connected to the wiring NL1c, and the wiring DLb is electrically connected to the wiring WL1.

Next, the barrier insulating film BI2 is formed on the insulating layer IL3 by, for example, the PECVD method. Thus, the wirings DLa and DLb are covered with the barrier insulating film BI2 made of a silicon carbonitride (SiCN) film.

Thereafter, through the process of forming other wirings on the barrier insulating film BI2, the process of forming a pad electrode and a passivation film in the further upper layer, and the process of dicing the substrate SB into a plurality of chips, the semiconductor device SD1 according to the present embodiment shown in FIG. 1 is completed.

<Background of Study>

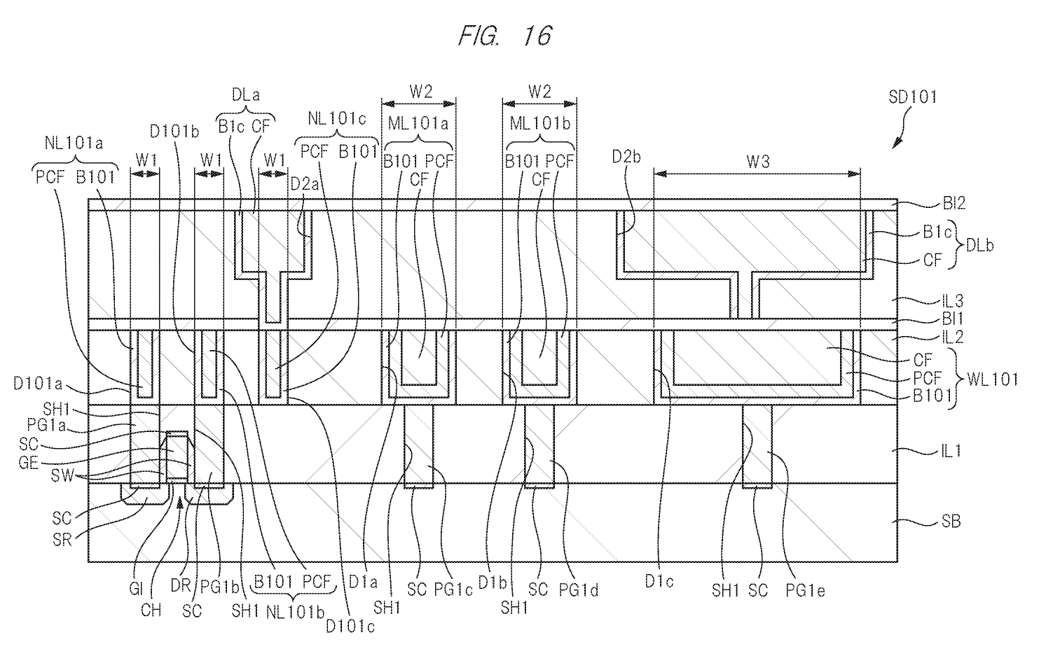

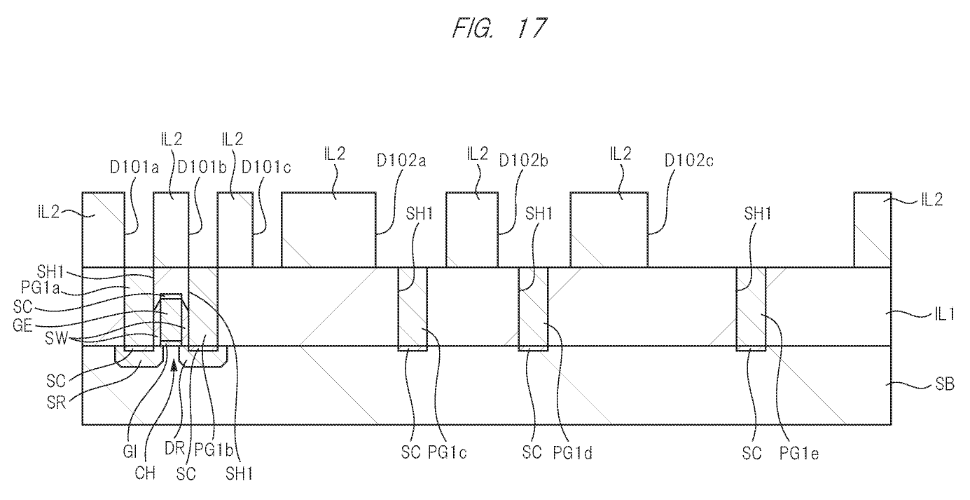

A configuration of a semiconductor device SD101 according to an example studied by the inventor of the present invention and a manufacturing method thereof will be described with reference to FIGS. 16 to 21. FIG. 16 is a cross-sectional view of a principal part of the semiconductor device SD101 according to the studied example. FIGS. 17 to 21 are cross-sectional views of a principal part in a manufacturing process of the semiconductor device SD101 according to the studied example.

As shown in FIG. 16, in the semiconductor device SD101 according to the studied example, the configuration in the thickness direction from the substrate SB to the insulating layer IL1 is the same as that of the semiconductor device SD1 according to the present embodiment shown in FIG. 1.

In the semiconductor device SD101 according to the studied example, wirings NL101a, NL101b, and NL101c are formed in the insulating layer IL2 (on the insulating layer IL1). The wirings NL101a, NL101b, and NL101c are buried in wiring trenches D101a, D101b, and D101c formed in the insulating layer IL2, respectively. Namely, the studied example is different from the present embodiment in that the wirings NL101a, NL101b, and NL101c are damascene wirings (damascene buried wirings) formed by the damascene method. The wirings NL101a, NL101b, and NL101c are each composed of a stacked film of a barrier conductor film B101 and the conductor film PCF.

The barrier conductor film B101 is composed of, for example, a tantalum nitride (TaN) film, a titanium nitride (TiN) film, or a stacked film of a tantalum nitride (TaN) film and a tantalum (Ta) film.

In addition, wirings ML101a and ML101b and a wiring WL101 are formed in the insulating layer IL2. The wirings ML101a and ML101b are buried in the wiring trenches D1a and D1b formed in the insulating layer IL2, respectively. The wiring WL101 is buried in the wiring trench D1c formed in the insulating layer IL2. The wirings NL101a and NL101b and the wiring WL101 are damascene wirings (damascene buried wirings) formed by the damascene method.

The wirings NL101a, NL101b, and NL101c, the wirings ML101a and ML101b, and the wiring WL101 are all formed in the insulating layer IL2. Also, the width of each of the wirings NL101a, NL101b, and NL101c is the same as the width W1 (see FIG. 1) of each of the wirings NL1a, NL1b, and NL1c. The width of each of the wirings ML101a and ML101b is the same as the width W2 (see FIG. 1) of each of the wirings ML1a and ML1b. The width of the wiring WL101 is the same as the width W3 (see FIG. 1) of the wiring WL1. Therefore, the width W1 of each of the wirings NL101a, NL101b, and NL101c is smaller (thinner, narrower) than the width W2 of each of the wirings ML101a and ML101b. Also, the width W2 of each of the wirings ML101a and ML101b is smaller (thinner, narrower) than the width W3 of the wiring WL101. Namely, the wirings NL101a, NL101b, and NL101c, the wirings ML101a and ML101b, and the wiring WL101 having different wiring widths are formed in the same layer (same wiring layer).

The studied example is different from the present embodiment in that the wirings ML101a and ML101b and the wiring WL101 are each composed of a stacked film of the barrier conductor film B101, the conductor film PCF, and the conductor film CF.

In the insulating layer IL1, the plug PG1a is arranged between the wiring NL101a and the source region SR of the MOSFET to electrically connect the wiring NL101a and the source region SR. The plug PG1b is arranged between the wiring NL101b and the drain region DR of the MOSFET to electrically connect the wiring NL101b and the drain region DR. The plug PG1c is arranged between, for example, the wiring ML101a and an element (not shown) to electrically connect the wiring ML101a and the element. The plug PG1d is arranged between, for example, the wiring ML101b and an element (not shown) to electrically connect the wiring ML101b and the element. The plug PG1e is arranged between, for example, the wiring WL101 and an element (not shown) to electrically connect the wiring WL101 and the element.

Also, in the insulating layer IL3, the wiring DLa penetrates the barrier insulating film BI1 and is electrically connected to the wiring NL101c. The wiring DLb penetrates the barrier insulating film BI1 and is electrically connected to the wiring WL101.

The other configuration of the semiconductor device SD101 according to the studied example is the same as that of the semiconductor device SD1 according to the present embodiment, and thus the repetitive description is omitted.

Next, a manufacturing method of the semiconductor device SD101 according to the studied example will be described with reference to FIGS. 17 to 21.

As described above, in the semiconductor device SD101 according to the studied example shown in FIG. 16, the configuration in the thickness direction from the substrate SB to the insulating layer IL1 is the same as that of the semiconductor device SD1 according to the present embodiment. Therefore, in the manufacturing method of the semiconductor device SD101 according to the studied example, the process from the preparation of the substrate SB to the formation of the plugs PG1a, PG1b, PG1c, PG1d, and PG1e (see FIGS. 2 to 5) is the same as that of the manufacturing method of the semiconductor device SD1 according to the present embodiment.

Thereafter, as shown in FIG. 17, for example, MSQ is coated to 60 to 90 nm on the insulating layer IL1, and then sintered to form the insulating layer IL2.

Next, as shown in FIG. 17, the insulating layer IL2 is patterned by the photolithography technique, the dry etching technique and the like to form wiring trenches D101a, D101b, D101c, D102a, D102b, and D102c. The width of each of the wiring trenches D101a, D101b, and D101c is smaller (narrower, narrower) than the width of each of the wiring trenches D102a and D102b. Also, the width of each of the wiring trenches D102a and D102b is smaller (thinner, narrower) than the width of the wiring trench D102c. The wiring trenches D101a, D101b, D102a, D102b, and D102c are formed so as to expose apart of the upper surface of the insulating layer IL1 including each upper surface of the plugs PG1a, PG1b, PG1c, PG1d, and PG1e, respectively.

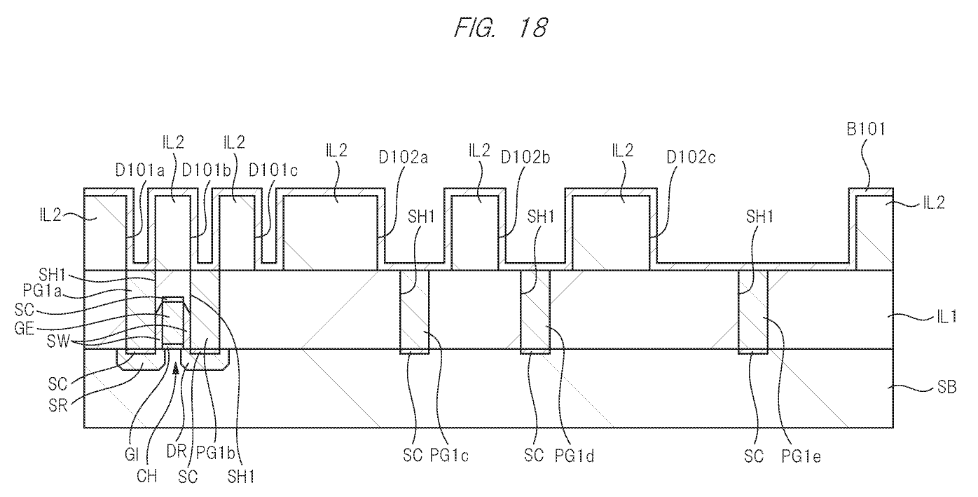

Next, as shown in FIG. 18, the barrier conductor film B101 made of, for example, tantalum nitride is formed on the insulating layer IL2 by, for example, the PVD method. Thus, the barrier conductor film B101 is formed on the bottoms and side walls of the wiring trenches D101a, D101b, D101c, D102a, D102b, and D102c.

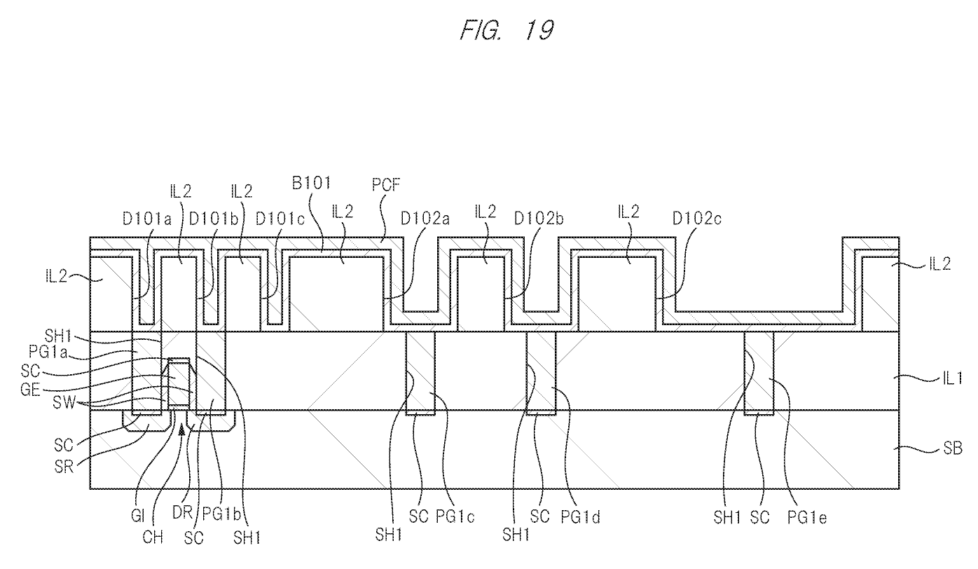

Next, as shown in FIG. 19, the conductor film PCF made of, for example, cobalt is formed on the barrier conductor film B101 by, for example, the CVD method. Herein, a formation film thickness of the conductor film PCF is a film thickness capable of completely filling the wiring trenches D101a, D101b, and D101c with the conductor film PCF and incapable of completely filling the wiring trenches D102a and D102b with the conductor film PCF. Thereafter, by performing the heat treatment (reflow), the wiring trenches D101a, D101b, and D101c are completely filled with the conductor film PCF. Meanwhile, the wiring trenches D102a and D102b are not completely filled with the conductor film PCF. In addition, at this time, since the width of the wiring trench D102c is larger than the width of each of the wiring trenches D102a and D102b, the wiring trench D102c is also not completely filled with the conductor film PCF.

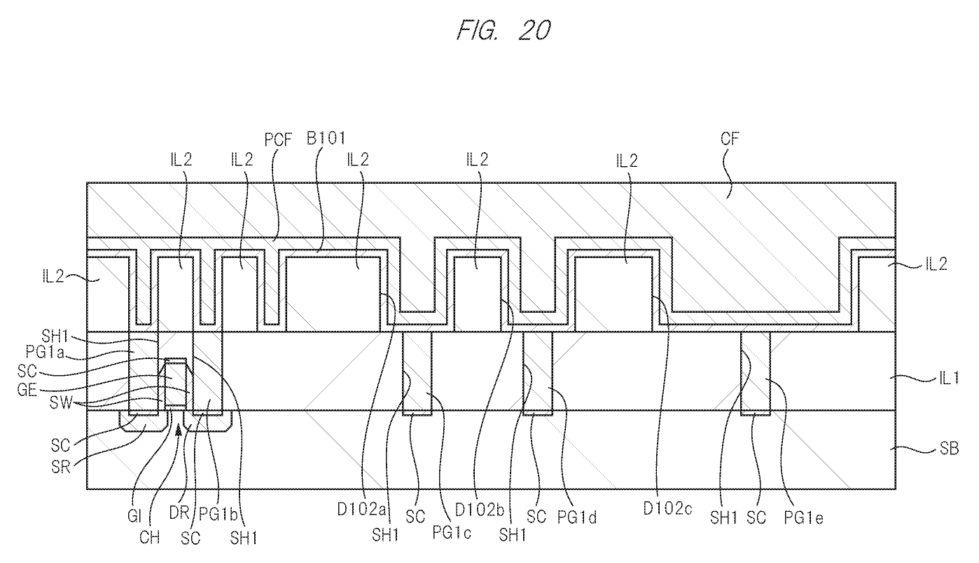

Next, though not shown, a seed film made of copper having a thickness of 30 to 50 nm is formed on the conductor film PCF by, for example, the PVD method. Then, as shown in FIG. 20, the conductor film CF made of copper having a thickness of 100 to 200 nm is formed on the seed film (not shown) by the electroplating method. Thereafter, the heat treatment is performed at about 450° C. for 30 minutes. Herein, since the wiring trenches D101a, D101b, and D101c are completely filled with the conductor film PCF, the conductor film CF does not enter the wiring trenches D101a, D101b, and D101c. Meanwhile, since the wiring trenches D102a, D102b, and D102c are not completely filled with the conductor film PCF, the conductor film CF enters the wiring trenches D102a, D102b, and D102c.

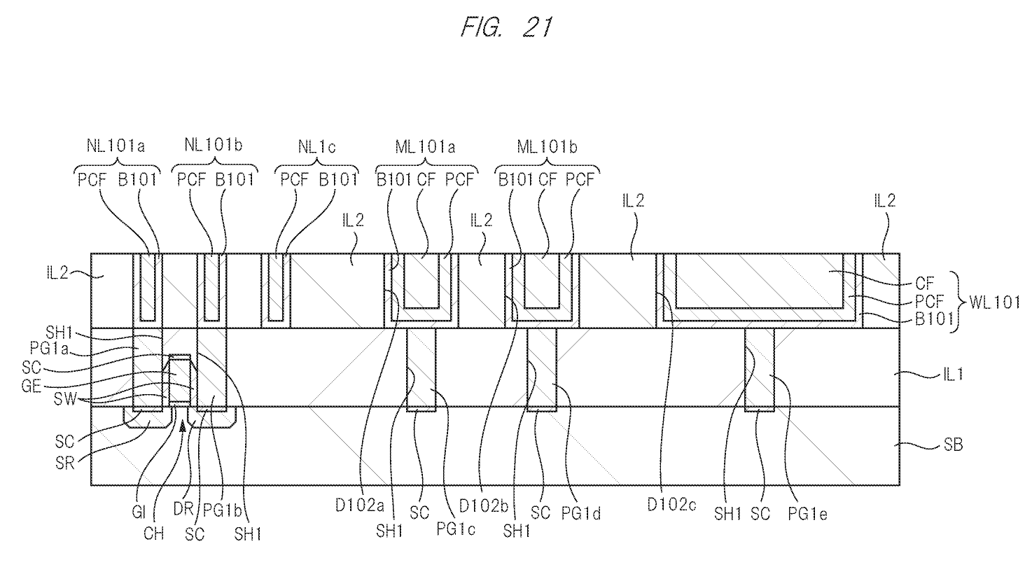

Next, as shown in FIG. 21, the barrier conductor film B101, the conductor film PCF, and the conductor film CF outside the wiring trenches D101a, D101b, D101c, D102a, D102b, and D102c are removed by the CMP method. Thus, the barrier conductor film B101 and the conductor film PCF are left in the wiring trenches D101a, D101b, and D101c. Also, the barrier conductor film B101, the conductor film PCF, and the conductor film CF are left in the wiring trenches D102a, D102b, and D102c. As a result, the wirings NL101a, NL101b, and NL101c composed of the barrier conductor film B101 and the conductor film PCF and the wirings ML101a and ML101b and the wiring WL101 composed of the barrier conductor film B101, the conductor film PCF, and the conductor film CF are formed on the insulating layer IL1.

Thereafter, through the process of forming the barrier insulating film BI1 on the insulating layer IL2 and subsequent process as in the process of the present embodiment, the semiconductor device SD101 according to the studied example shown in FIG. 16 is completed.

Hereinafter, the problem newly found by the inventor of the present invention in the semiconductor device SD101 according to the studied example will be described. As described above, in the semiconductor device SD101 according to the studied example, the wirings NL101a, NL101b, and NL101c, the wirings ML101a and ML101b, and the wiring WL101 having different wiring widths are formed in the same layer (same wiring layer). For example, thin wirings having small wiring width such as the wirings NL101a, NL101b, and NL101c are used as signal wirings to transmit signals, and wide wirings having large wiring width such as the wirings ML101a and ML101b and the wiring WL101 are used as power supply wirings to supply power supply potential.

Hereinafter, when compared among the wirings formed in the same wiring layer, the wiring having the smallest wiring width is simply referred to as “wiring having small wiring width” in some cases. Also, when compared among the wirings formed in the same wiring layer, the wiring having the wiring width larger than that of the wiring having the smallest wiring width is simply referred to as “wiring having large wiring width” in some cases.

Herein, a copper wiring mainly containing copper is frequently used for the wirings. Copper has advantages of low electrical resistance and low material cost compared with other metals. However, it has been found that, when the wiring width of the wiring made of copper becomes small (the aspect ratio thereof increases), the surface scattering due to the increase in surface proportion and the grain boundary scattering due to the grain size become conspicuous (size effect), so that the resistance of the wiring increases. Specifically, in the case of the wiring made of copper, the size effect increases when the wiring width becomes about 100 nm or less. In particular, it has been found that, when the wiring width becomes about 15 nm or less, the resistance of the wiring made of copper becomes larger than the resistance of a wiring made of metal whose electrical resistivity in bulk is originally larger than that of copper, due to the size effect.

It is known that the increase in resistance due to the surface scattering and the grain boundary scattering described above is proportional to the product of the bulk electrical resistivity and the mean free path of electrons. Therefore, it is conceivable that a metal whose bulk electrical resistivity is almost equal to that of copper and whose mean free path of electrons is smaller than that of copper or an alloy of such metals is adopted as a wiring material (hereinafter, such a metal and an alloy of such metals are referred to as “post copper materials”). Examples of the post copper material include cobalt (Co), tungsten (W), ruthenium (Ru), molybdenum (Mo), aluminum (Al), nickel (Ni), rhodium (Rh), iridium (Ir), zinc (Zn), cobalt ruthenium (CoRu), and cobalt aluminum (CoAl). However, when the post copper material is used as the material of the wiring having large wiring width, that is, the wiring having the wiring width of about 15 nm or larger, since the influence of the size effect is small, the resistance of the wiring increases as compared with the case of using copper. Therefore, it is conceivable that copper is adopted as the material of the wiring having large wiring width (wiring width of 15 nm or larger) and the post copper material is used as the material of the wiring having small wiring width (wiring width of 15 nm or smaller).

Note that, when wirings having different wiring widths are formed in different wiring layers, it is easy to change the materials of the wirings, but when wirings having different wiring widths are formed in the same wiring layer, it is necessary to devise the structure and the manufacturing process thereof.

Therefore, as described above, in the manufacturing method of the semiconductor device SD101 according to the studied example, the wiring trenches D101a, D101b, and D101c are formed so as to be completely filled with the conductor film PCF made of the post copper material and the wiring trenches D102a, D102b, and D102c are formed so as not to be completely filled with the conductor film PCF as shown in FIG. 19. Then, the conductor film CF made of copper is formed on the conductor film PCF, and the barrier conductor film B101, the conductor film PCF, and the conductor film CF outside the wiring trenches D101a, D101b, D101c, D102a, D102b, and D102c are removed by the CMP method.

In this manner, the wirings NL101a, NL101b, and NL101c having small wiring width can be composed of the barrier conductor film B101 and the conductor film PCF made of the post copper material. Further, the wirings ML101a and ML101b and the wiring WL101 having large wiring width can be composed of the barrier conductor film B101, the conductor film PCF made of the post copper material, and the conductor film CF made of copper. As a result, in the semiconductor device SD101 according to the studied example, the resistance of the wiring having small wiring width can be reduced as compared with the case in which the wiring is all made of copper.

However, the semiconductor device SD101 according to the studied example has two problems. First, in the wirings NL101a, NL101b, and NL101c having small wiring width, the barrier conductor film B101 is formed on the bottoms and side walls of the wirings NL101a, NL101b, and NL101c in order to bury the conductor film PCF by the damascene method. Since the wirings NL101a, NL101b, and NL101c have the wiring width smaller than those of other wirings, the proportion of the barrier conductor film B101 is large in the wirings NL101a, NL101b, and NL101c. In addition, tantalum nitride constituting the barrier conductor film B101 has the bulk electrical resistivity larger than any of copper and the post copper material. As a result, in the studied example, although the wirings NL101a, NL101b, and NL101c having small wiring width are made of the post copper material, it is not possible to effectively reduce the wiring resistance of these wirings as compared with the case where these wirings are made of copper.

Also, the wirings ML101a and ML101b and the wiring WL101 having large wiring width include not only the conductor film CF made of copper but also the conductor film PCF made of the post copper material in view of the manufacturing process described above. As described above, when the post copper material is used as the wiring material of the wiring having large wiring width, the resistance of the wiring increases as compared with the case of using copper because the influence of the size effect is small. As a result, in the studied example, the wiring resistance of the wirings ML101a and ML101b and the wiring WL101 having large wiring width cannot be reduced as compared with the case where these wirings are made of copper.

From the foregoing, it is desired to improve the performance of the semiconductor device by reducing the resistance of the wirings having different wiring widths formed in the same wiring layer.

### Main Feature of Present Embodiment

Hereinafter, the main feature and effect of the present embodiment will be described. One of main features of the present embodiment is that, among the wirings NL1a, NL1b, and NL1c, the wirings ML1a and ML1b, and the wiring WL1 formed in the same wiring layer, the wirings NL1a, NL1b, and NL1c having small wiring width are each composed of a stacked film of the barrier conductor film B1a, the conductor film PCF made of the post copper material, and the barrier conductor film B1b as shown in FIG. 1. Also, the barrier conductor films B1a and B1b are not formed on the side surfaces of the wirings NL1a, NL1b, and NL1c. In addition, among the wirings NL1a, NL1b, and NL1c, the wirings ML1a and ML1b, and the wiring WL1 formed in the same wiring layer, the wirings ML1a and ML1b and the wiring WL1 having large wiring width are composed of the barrier conductor film B1c and the conductor film CF made of copper.

Further, in the manufacturing method of the semiconductor device SD1 according to the present embodiment, the barrier conductor film B1a, the conductor film PCF, and the barrier conductor film B1b are formed on the insulating layer IL1 in sequence as shown in FIG. 6, and then, the barrier conductor film B1a, the conductor film PCF, and the barrier conductor film B1b are patterned with using the photoresist films PR2a, PR2b, and PR2c as a mask as shown in FIGS. 7 and 8. In this manner, the wirings NL1a, NL1b, and NL1c composed of the stacked film of the barrier conductor film B1a, the conductor film PCF made of the post copper material, and the barrier conductor film B1b are formed.

Subsequently, as shown in FIGS. 9 to 12, the insulating layer IL2 is formed on the insulating layer IL1 so as to cover the wirings NL1a, NL1b, and NL1c, and then, the insulating layer IL2 is patterned with using the photoresist film PR3 as a mask, thereby forming the wiring trenches D1a, D1b, and D1c in the insulating layer IL2. Thereafter, as shown in FIGS. 13 to 15, the barrier conductor film B1c and the conductor film CF are buried in the wiring trenches D1a, D1b, and D1c, and then, the barrier conductor film B1c and the conductor film CF outside the wiring trenches D1a, D1b, and D1c are removed by the CMP method. In this manner, the wirings ML1a and ML1b and the wiring WL1 composed of the barrier conductor film B1c and the conductor film CF made of copper are formed.

In the present embodiment, the configuration and the process described above are adopted, and it is thus possible to improve the performance of the semiconductor device. Hereinafter, the reason therefor will be described.

First, in the present embodiment, among the wirings formed in the same wiring layer, the wirings NL1a, NL1b, and NL1c having small wiring width are composed of the barrier conductor film B1a, the conductor film PCF made of the post copper material, and the barrier conductor film B1b. Also, the barrier conductor films B1a and B1b are formed only on bottoms and upper portions of the wirings NL1a, NL1b, and NL1c, and are not formed on side surfaces of the wirings NL1a, NL1b, and NL1c. Namely, the proportion of the barrier conductor films B1a and B1b in the wirings NL1a, NL1b, and NL1c is small. As a result, in the present embodiment, it is possible to effectively reduce the wiring resistance of the wirings NL1a, NL1b, and NL1c having small wiring width as compared with the case where the wirings NL1a, NL1b, and NL1c having small wiring width are all made of copper and the case of the wirings NL101a, NL101b, and NL101c according to the studied example.

Also, in the present embodiment, the wirings ML1a and ML1b and the wiring WL1 having a wiring width larger than those of the wirings NL1a, NL1b, and NL1c are composed of the barrier conductor film B1c and the conductor film CF made of copper. Therefore, it is possible to reduce the wiring resistance of the wirings ML1a and ML1b and the wiring WL1 having large wiring width as compared with the wirings ML101a and ML101b and the wiring WL101 according to the studied example.

As described above, in the present embodiment, it is possible to improve the performance of the semiconductor device by reducing the resistance of the wirings having different wiring widths formed in the same wiring layer.

Note that, when the wiring resistance of the wiring having small wiring width is to be reduced, aluminum, iridium, indium, and rhodium whose product of the bulk electrical resistivity and the mean free path of electrons is small among the post copper materials are preferably adopted as the post copper material constituting the conductor film PCF.

In addition, when the easiness of the etching is prioritized, tungsten is preferably adopted as the post copper material constituting the conductor film PCF. This is because the vapor pressure of the reactant WF₆ between tungsten and fluorine-based gas (for example, mixed gas of SF₆ and CHF₃) is high and it can be removed as a gas.

Further, it has been known that cobalt ruthenium has good adhesion with tantalum nitride or the like used as the barrier conductor film, among the post copper materials. Therefore, when the adhesion to the barrier conductor film in the wiring is prioritized, cobalt ruthenium is preferably adopted as the post copper material constituting the conductor film PCF.

Also, in the present embodiment, the barrier conductor film B1b is formed on the conductor film PCF in the wirings NL1a, NL1b, and NL1c. Accordingly, it is possible to prevent the upper surface of the conductor film PCF from being damaged in the process of removing the photoresist films PR2a, PR2b, and PR2c by the etching using organic solvent containing organic acid or the oxygen plasma asking.

Note that, in the present embodiment, the barrier conductor film B1a, the barrier conductor film B1b, and the barrier conductor film B1c are formed in respectively different processes, and it is thus possible to change the film thicknesses thereof. The advantage thereof will be described based on an example.

As described above, tantalum nitride constituting the barrier conductor film B1a has the bulk electrical resistivity larger than those of copper and the post copper materials. Therefore, in order to reduce the wiring resistance, it is preferable that the barrier conductor film B1a is formed to be thin. However, if the film thickness of the barrier conductor film B1c is too small in the wirings ML1a and ML1b and the wiring WL1 having large wiring width, diffusion of copper constituting the conductor film CF cannot be prevented. Therefore, it is preferable to secure the film thickness of the barrier conductor film B1c to some extent.

Meanwhile, the post copper material constituting the conductor film PCF of the wirings NL1a, NL1b, and NL1c having small wiring width among the wirings formed in the same wiring layer is less likely to be diffused than copper. Therefore, the barrier conductor film B1a is formed for securing the adhesion between the insulating layer IL1 and the conductor film PCF made of the post copper material and securing the crystallinity of the conductor film PCF, rather than for preventing the diffusion of the post copper material. Therefore, it is preferable that the barrier conductor film B1a is formed to be as thin as possible.

Therefore, since the barrier conductor film B1a and the barrier conductor film B1c are formed in respectively different processes in the present embodiment, the barrier conductor film B1a can be formed as thin as possible and the barrier conductor film B1c can be formed to be thicker than the barrier conductor film B1a, so that the requirements described above can be satisfied.

<First Modification>

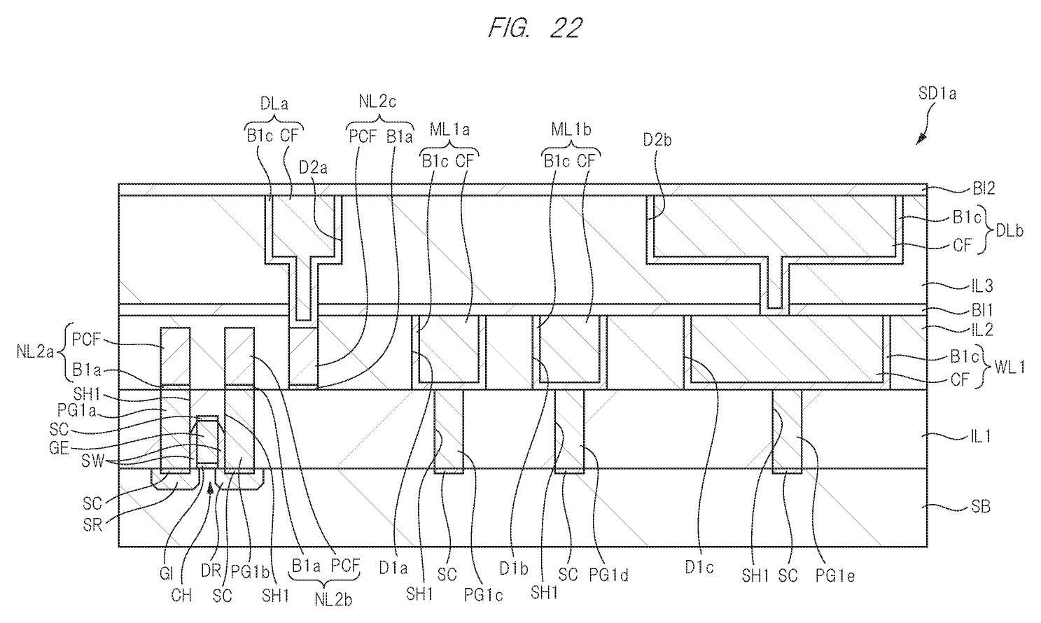

A configuration of a semiconductor device SD1a according to a first modification and a manufacturing method thereof will be described with reference to FIG. 22. FIG. 22 is a cross-sectional view of a principal part of the semiconductor device SD1a according to the first modification.

As shown in FIG. 22, in the semiconductor device SD1a according to the first modification, wirings NL2a, NL2b, and NL2c are formed in the insulating layer IL2. Also, a width of each of the wirings NL2a, NL2b, and NL2c is smaller than a width of each of the wirings ML1a and ML1b formed in the insulating layer IL2 (in the same wiring layer). The wirings NL2a, NL2b, and NL2c are each composed of a stacked film of the barrier conductor film B1a and the conductor film PCF, and the barrier conductor film B1b is not formed on the conductor film PCF. Also, the wiring DLa is electrically connected to the wiring NL2c by penetrating the barrier insulating film BI1 to be in contact with the conductor film PCF.

This point is the difference between the wirings NL2a, NL2b, and NL2c according to the first modification and the wirings NL1a, NL1b, and NL1c of the semiconductor device SD1 according to the present embodiment described above. The other configuration of the semiconductor device SD1a according to the first modification is the same as that of the semiconductor device SD1 according to the present embodiment, and thus the repetitive description is omitted.

In addition, the manufacturing method of the semiconductor device SD1a according to the first modification does not include the process of forming the barrier conductor film B1b on the conductor film PCF shown in FIG. 6 unlike the present embodiment described above. Therefore, a photoresist film is formed on the conductor film PCF, and the photoresist film is patterned to form the photoresist films PR2a, PR2b, and PR2c on the conductor film PCF (see FIG. 7). This point is the difference between the first modification and the present embodiment described above, the other process is the same as that of the present embodiment, and thus the repetitive description is omitted.

As described above, tantalum nitride constituting the barrier conductor film B1b has the bulk electrical resistivity larger than those of copper and the post copper material. Therefore, the wiring resistance of the wirings NL2a, NL2b, and NL2c including no barrier conductor film B1b is smaller than that of the wirings NL1a, NL1b, and NL1c including the barrier conductor film B1b. As a result, the semiconductor device SD1a according to the first modification is more advantageous than the semiconductor device SD1 according to the present embodiment described above in that it is possible to reduce the resistance of the wiring having small wiring width among the wirings formed in the same wiring layer.

Meanwhile, as described above, it is possible to prevent the upper surface of the conductor film PCF from being damaged in the process of removing the photoresist films PR2a, PR2b, and PR2c by the presence of the barrier conductor film B1b in the present embodiment described above. Therefore, the semiconductor device SD1 according to the present embodiment is more advantageous in this point than the semiconductor device SD1a according to the first modification.

In the first modification, the case where the conductor film PCF constituting the wirings NL2a, NL2b, and NL2c having small wiring width among the wirings formed in the same wiring layer is formed by the dry etching (anisotropic etching) has been described, but it is also possible to form the conductor film PCF by, for example, the selective CVD method.

Specifically, after forming the barrier conductor film B1a constituting the wirings NL2a, NL2b, and NL2c (the same configuration as that without the conductor film PCF and the barrier conductor film B1b in FIG. 6), though not shown, the barrier conductor film B1a is patterned by the photolithography technique, the dry etching technique and the like. Thereafter, the conductor film PCF made of, for example, cobalt of the post copper material is selectively grown only in a portion where the barrier conductor film B1a is present by the selective CVD method. In this manner, the wirings NL2a, NL2b, and NL2c can be formed (the same configuration as that without the photoresist films PR2a, PR2b, and PR2c and the barrier conductor film B1b in FIG. 8 is obtained). Through the process subsequent thereto, the semiconductor device SD1a according to the first modification shown in FIG. 22 can be formed.

According to this method, even the material for which the dry etching is difficult among the post copper materials, it is possible to form the wirings NL2a, NL2b, and NL2c by using those materials.

<Second Modification>

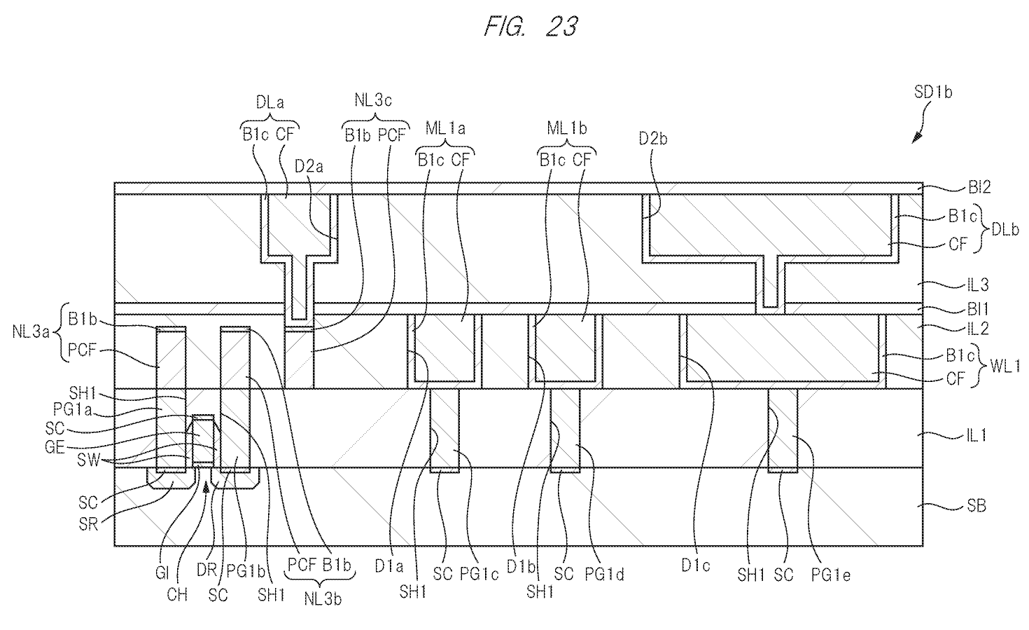

A configuration of a semiconductor device SD1b according to a second modification and a manufacturing method thereof will be described with reference to FIG. 23. FIG. 23 is a cross-sectional view of a principal part of the semiconductor device SD1b according to the second modification.

As shown in FIG. 23, in the semiconductor device SD1b according to the second modification, wirings NL3a, NL3b, and NL3c are formed in the insulating layer IL2. Also, a width of each of the wirings NL3a, NL3b, and NL3c is smaller than a width of each of the wirings ML1a and ML1b formed in the insulating layer IL2 (in the same wiring layer). The wirings NL3a, NL3b, and NL3c are each composed of a stacked film of the conductor film PCF and the barrier conductor film B1b, and the barrier conductor film B1a is not formed below the conductor film PCF. Also, the wiring DLa is electrically connected to the wiring NL3c by penetrating the barrier insulating film BI1.

This point is the difference between the wirings NL3a, NL3b, and NL3c according to the second modification and the wirings NL1a, NL1b, and NL1c of the semiconductor device SD1 according to the present embodiment described above. The other configuration of the semiconductor device SD1b according to the second modification is the same as that of the semiconductor device SD1 according to the present embodiment, and thus the repetitive description is omitted.

In addition, the manufacturing method of the semiconductor device SD1b according to the second modification does not include the process of forming the barrier conductor film B1a on the insulating layer IL2 shown in FIG. 6 unlike the present embodiment described above. Therefore, the conductor film PCF is formed on the insulating layer IL2. This point is the difference between the second modification and the present embodiment described above, the other process is the same as that of the present embodiment, and thus the repetitive description is omitted.

As described above, tantalum nitride constituting the barrier conductor film B1b has the bulk electrical resistivity larger than those of copper and the post copper material. Therefore, the wiring resistance of the wirings NL3a, NL3b, and NL3c including no barrier conductor film B1a is smaller than that of the wirings NL1a, NL1b, and NL1c including the barrier conductor film B1a. As a result, the semiconductor device SD1b according to the second modification is more advantageous than the semiconductor device SD1 according to the present embodiment described above in that it is possible to reduce the resistance of the wiring having small wiring width among the wirings formed in the same wiring layer.

Meanwhile, since the barrier conductor film B1a is provided between the insulating layer IL1 and the conductor film PCF in the present embodiment described above, it is possible to secure the adhesion between the insulating layer IL1 and the conductor film PCF and the crystallinity of the conductor film PCF. In this respect, the semiconductor device SD1 according to the present embodiment described above is more advantageous than the semiconductor device SD1b according to the second modification.

<Third Modification>

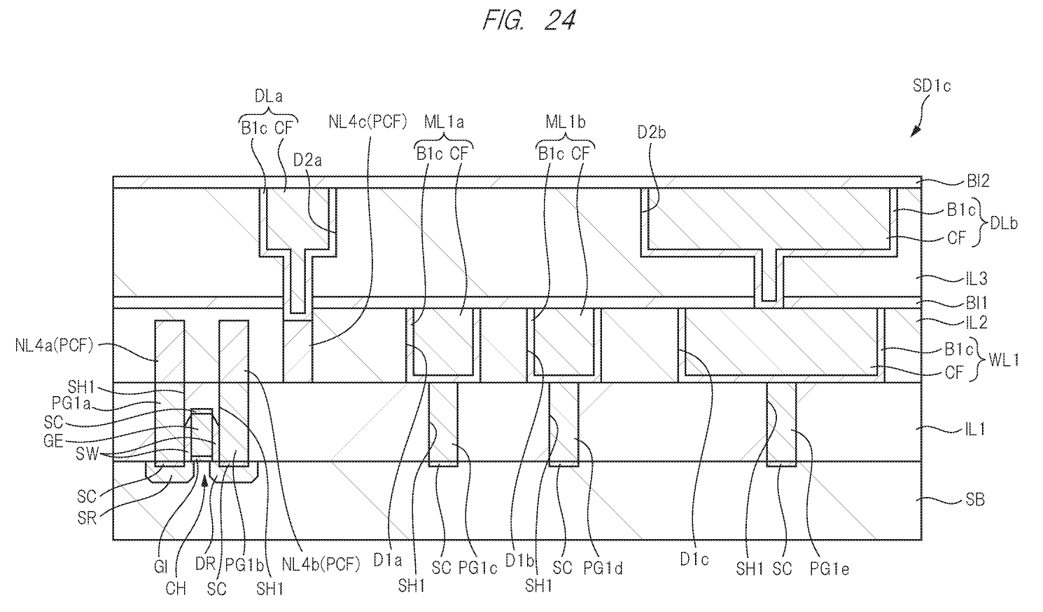

A configuration of a semiconductor device SD1c according to a third modification and a manufacturing method thereof will be described with reference to FIG. 24. FIG. 24 is a cross-sectional view of a principal part of the semiconductor device SD1c according to the third modification.

As shown in FIG. 24, in the semiconductor device SD1c according to the third modification, wirings NL4a, NL4b, and NL4c are formed in the insulating layer IL2. Also, a width of each of the wirings NL4a, NL4b, and NL4c is smaller than a width of each of the wirings ML1a and ML1b formed in the insulating layer IL2 (in the same wiring layer). The wirings NL4a, NL4b, and NL4c are each composed of only the conductor film PCF, the barrier conductor film B1a is not formed below the conductor film PCF, and the barrier conductor film B1b is not formed on the conductor film PCF. Also, the wiring DLa is electrically connected to the wiring NL4c by penetrating the barrier insulating film BI1 to be in contact with the conductor film PCF.

This point is the difference between the wirings NL4a, NL4b, and NL4c according to the third modification and the wirings NL1a, NL1b, and NL1c of the semiconductor device SD1 according to the present embodiment described above. The other configuration of the semiconductor device SD1c according to the third modification is the same as that of the semiconductor device SD1 according to the present embodiment, and thus the repetitive description is omitted.

Also, the manufacturing method of the semiconductor device SD1c according to the third modification does not include the process of forming the barrier conductor film B1a on the insulating layer IL2 and the process of forming the barrier conductor film B1b on the conductor film PCF shown in FIG. 6 unlike the present embodiment described above. Therefore, the conductor film PCF is formed on the insulating layer IL2. Also, a photoresist film is formed on the conductor film PCF, and the photoresist film is patterned to form the photoresist films PR2a, PR2b, and PR2c on the conductor film PCF (see FIG. 7). This point is the difference between the third modification and the present embodiment described above, the other process is the same as that of the present embodiment, and thus the repetitive description is omitted.

As described above, tantalum nitride constituting the barrier conductor film B1b has the bulk electrical resistivity larger than those of copper and the post copper material. Therefore, the wiring resistance of the wirings NL4a, NL4b, and NL4c including no barrier conductor films B1a and B1b is smaller than that of the wirings NL1a, NL1b, and NL1c, the wirings NL2a, NL2b, and NL2c, and the wirings NL3a, NL3b, and NL3c including the barrier conductor film B1a and/or the barrier conductor film B1b. As a result, the semiconductor device SD1c according to the third modification is most advantageous among the semiconductor device SD1 according to the present embodiment described above, the semiconductor device SD1a according to the first modification, the semiconductor device SD1b according to the second modification, and the semiconductor device SD1c according to the third modification in that it is possible to reduce the resistance of the wiring having small wiring width among the wirings formed in the same wiring layer.

Meanwhile, since the barrier conductor film B1a is provided between the insulating layer IL1 and the conductor film PCF in the present embodiment described above and the first modification, it is possible to secure the adhesion between the insulating layer IL1 and the conductor film PCF and the crystallinity of the conductor film PCF. In this respect, the semiconductor device SD1 according to the present embodiment described above and the semiconductor device SD1a according to the first modification are more advantageous than the semiconductor device SD1c according to the third modification.

In addition, as described above, it is possible to prevent the upper surface of the conductor film PCF from being damaged in the process of removing the photoresist films PR2a, PR2b, and PR2c by the presence of the barrier conductor film B1b in the present embodiment described above and the second modification. Therefore, the semiconductor device SD1 according to the present embodiment and the semiconductor device SD1b according to the second modification are more advantageous in this point than the semiconductor device SD1c according to the third modification.

### Second Embodiment

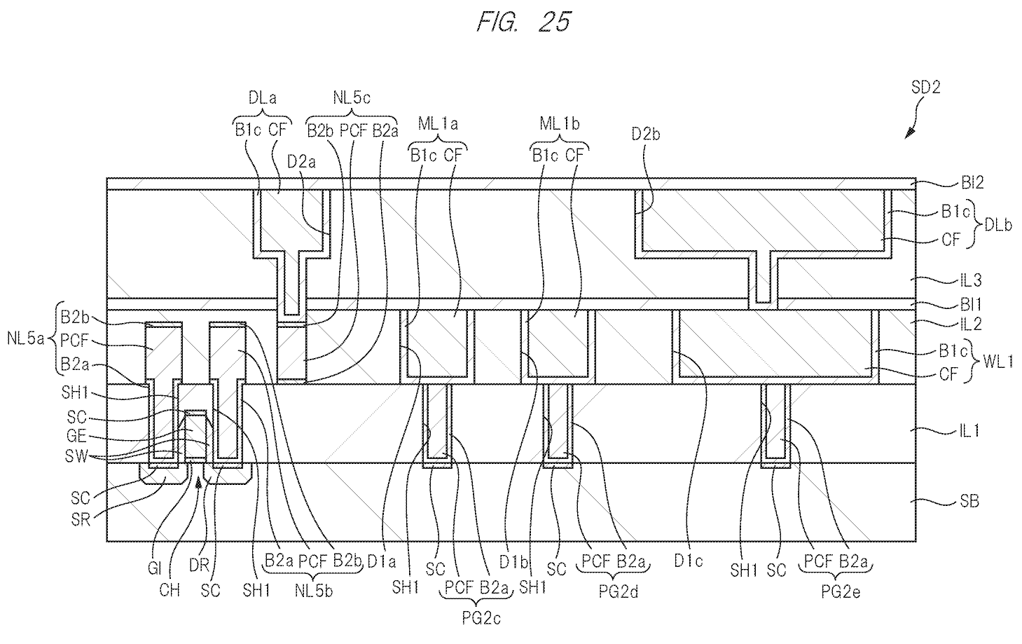

A configuration of a semiconductor device SD2 according to a second embodiment will be described with reference to FIG. 25. FIG. 25 is a cross-sectional view of a principal part of the semiconductor device SD2 according to the second embodiment.

As shown in FIG. 25, in the semiconductor device SD2 according to the second embodiment, wirings NL5a, NL5b, and NL5c are formed in the insulating layer IL1 and the insulating layer IL2. The wirings NL5a and NL5b are each composed of a barrier conductor film B2a that covers a side wall and a bottom surface of the through hole SH1 and a part of an outer portion of the through hole SH1, the conductor film PCF that is completely buried in the through hole SH1 via the barrier conductor film B2a and is further formed on the through hole SH1, and a barrier conductor film B2b formed on the conductor film PCF. Namely, the wiring NL5a according to the second embodiment has the structure in which the wiring NL1a and the plug PG1a according to the first embodiment shown in FIG. 1 are formed integrally with each other. Likewise, as shown in FIG. 25, the wiring NL5b according to the second embodiment has the structure in which the wiring NL1b and the plug PG1b according to the first embodiment shown in FIG. 1 are formed integrally with each other. The wiring NL5c is composed of a stacked film of the barrier conductor film B2a, the conductor film PCF, and the barrier conductor film B2b.

Also, conductive plugs PG2c, PG2d, and PG2e are formed in the insulating layer IL1. The plugs PG2c, PG2d, and PG2e are each composed of the barrier conductor film B2a that covers aside wall and a bottom surface of the through hole SH1 and a part of an outer portion of the through hole SH1 and the conductor film PCF that is completely buried in the through hole SH1 via the barrier conductor film B2a.

A width of apart of each of the wirings NL5a and NL5b formed in the insulating layer IL1 is the same as a width of each of the plugs PG2c, PG2d, and PG2e. Also, a width of a part of each of the wirings NL5a and NL5b formed in the insulating layer IL2 and a width of the wiring NL5c are smaller than a width of each of the wirings ML1a and ML1b formed in the insulating layer IL2 (in the same wiring layer).

The wiring NL5a is arranged on the source region SR of the MOSFET via the silicide layer SC, and the wiring NL5b is arranged on the drain region DR of the MOSFET via the silicide layer SC. Though not shown, the plugs PG2c, PG2d, and PG2e are the wirings to be connected to the element formed on the substrate SB, and the plugs PG2c, PG2d, and PG2e are also arranged on the silicide layers SC formed on the substrate SB.

In addition, the wiring DLa is electrically connected to the wiring NL5c by penetrating the barrier insulating film BI1 to be in contact with the barrier conductor film B2b.

The other configuration of the semiconductor device SD2 according to the second embodiment is the same as that of the semiconductor device SD1 according to the first embodiment described above, and thus the repetitive description is omitted.

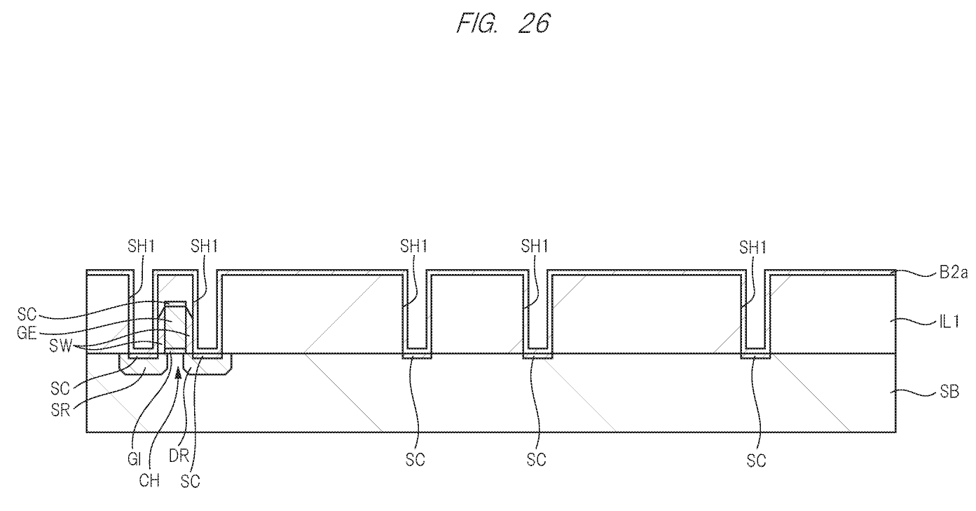

Next, a manufacturing method of the semiconductor device SD2 according to the second embodiment will be described in order of processes with reference to FIGS. 26 to 30. FIGS. 26 to 30 are cross-sectional views of a principal part in the manufacturing process of the semiconductor device SD2 according to the second embodiment, and each show the cross-section corresponding to FIG. 25 shown above.

In the manufacturing method of the semiconductor device SD2 according to the second embodiment shown in FIG. 25, the process from the preparation of the substrate SB to the formation of the through holes SH1 (see FIGS. 2 to 4) is the same as that of the manufacturing method of the semiconductor device SD1 according to the first embodiment described above.

Thereafter, as shown in FIG. 26, the barrier conductor film B2a made of, for example, tantalum nitride is formed to 1 to 3 nm on the insulating layer IL1 by, for example, the MOCVD (Metal Organic Chemical Vapor Deposition) method. Thus, the barrier conductor film B2a is formed on the bottom and side wall of the through hole SH1. Herein, since it is necessary to bury the barrier conductor film B2a in the through hole SH1, the MOCVD method with better burying property as compared with the PVD method is used as the method of forming the barrier conductor film B2a.

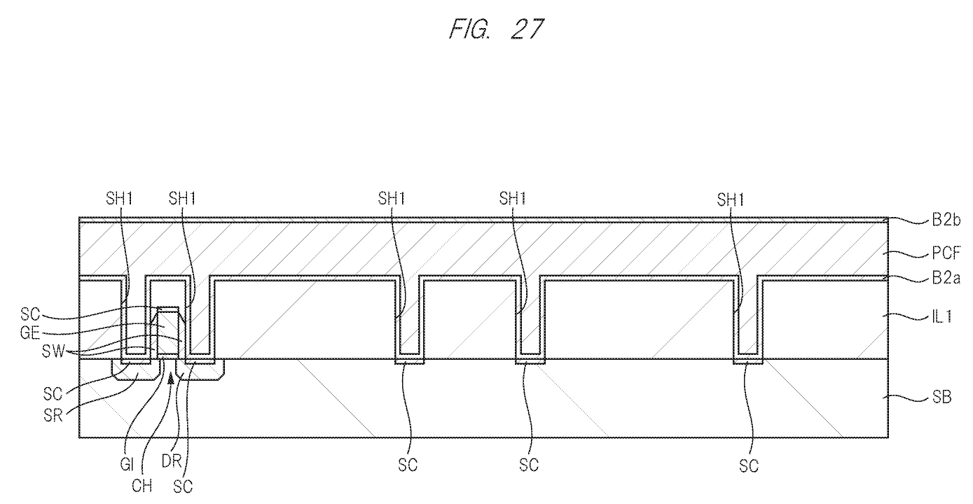

Next, as shown in FIG. 27, the conductor film PCF made of, for example, cobalt is formed to 30 to 60 nm on the barrier conductor film B2a by, for example, the CVD method. Thereafter, by performing the heat treatment (reflow), the through hole SH1 is completely filled with the conductor film PCF. Herein, since it is necessary to bury the conductor film PCF in the through hole SH1, the CVD method with better burying property as compared with the PVD method is used as the method of forming the conductor film PCF.

Next, as shown in FIG. 27, the barrier conductor film B2b made of, for example, tantalum nitride is formed to 1 to 3 nm on the conductor film PCF by, for example, the PVD method.

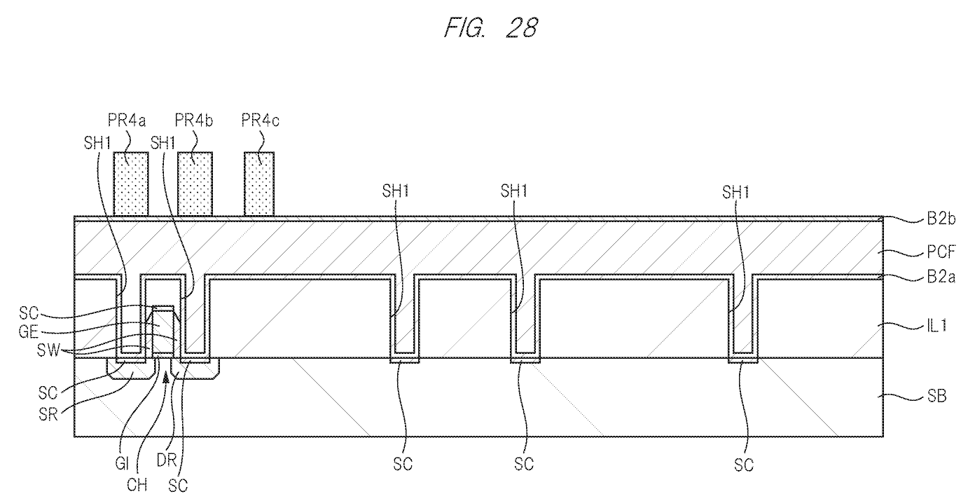

Next, as shown in FIG. 28, a photoresist film is formed on the barrier conductor film B2b, and the photoresist film is patterned to form photoresist films PR4a, PR4b, and PR4c.

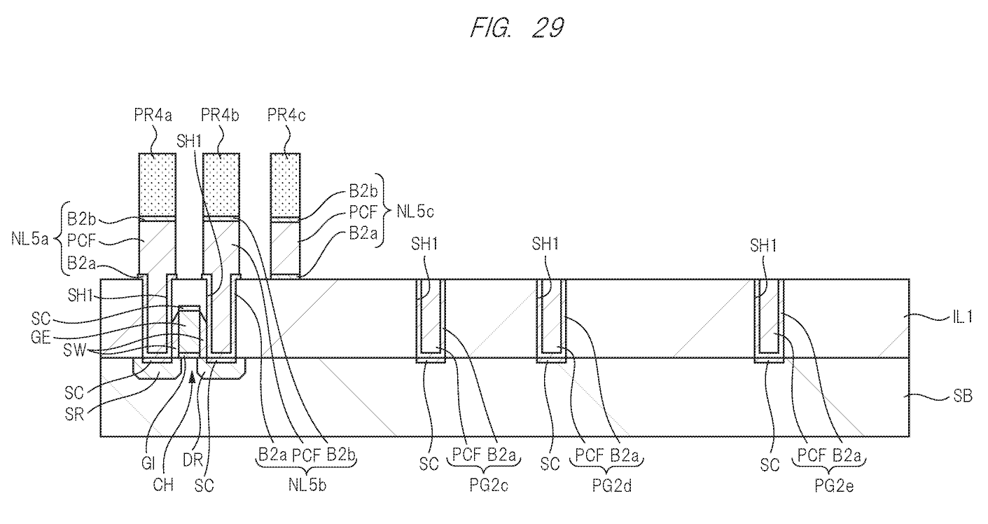

Next, as show in FIG. 29, the barrier conductor film B2a, the conductor film PCF, and the barrier conductor film B2b are patterned by the dry etching using fluorine gas at about 200 to 300° C. with using the photoresist films PR4a, PR4b, and PR4c as a mask.

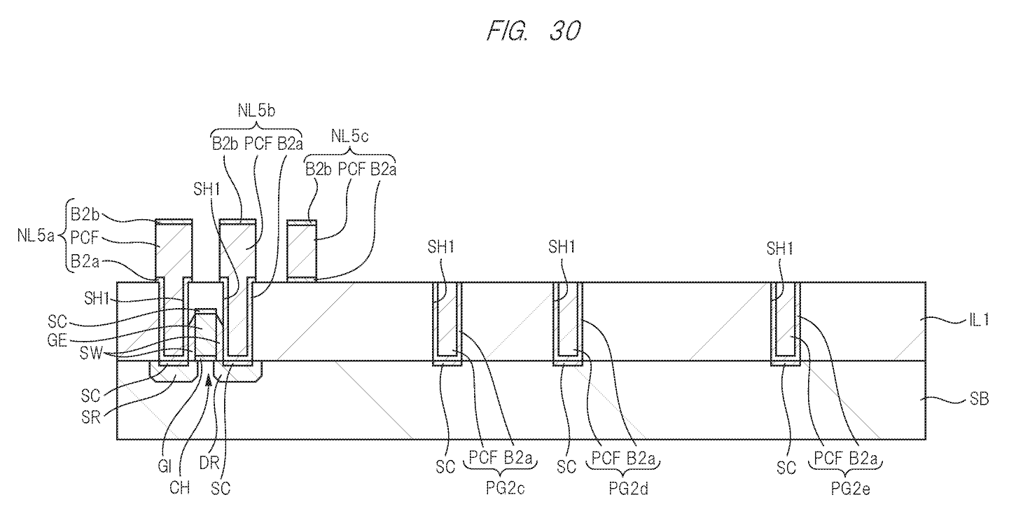

Next, as shown in FIG. 30, the photoresist films PR4a, PR4b, and PR4c are removed by the etching using organic solvent containing organic acid or the oxygen plasma asking. Thus, the wirings NL5a and NL5b each composed of the barrier conductor film B2a that covers the side wall and the bottom surface of the through hole SH1 and a part of the outer portion of the through hole SH1, the conductor film PCF that is completely buried in the through hole SH1 via the barrier conductor film B2a and is further formed on the through hole SH1, and the barrier conductor film B2b formed on the conductor film PCF are formed. In addition, the wiring NL5c composed of a stacked film of the barrier conductor film B2a, the conductor film PCF, and the barrier conductor film B2b is formed. Further, the plugs PG2c, PG2d, and PG2e each composed of the barrier conductor film B2a that covers the side wall and the bottom surface of the through hole SH1 and a part of the outer portion of the through hole SH1 and the conductor film PCF that is completely buried in the through hole SH1 via the barrier conductor film B2a are formed.

Thereafter, through the process of forming the insulating layer IL2 on the insulating layer IL1 so as to cover the wirings NL5a, NL5b, and NL5c (see FIG. 9) and subsequent process as in the process of the first embodiment described above, the semiconductor device SD2 according to the second embodiment shown in FIG. 25 is completed.

As shown in FIG. 25, in the semiconductor device SD2 according to the second embodiment, the wiring NL5a corresponds to the wiring in which the plug PG1a and the wiring NL1a according to the first embodiment are formed integrally with each other. Also, the wiring NL5b corresponds to the wiring in which the plug PG1b and the wiring NL1b according to the first embodiment are formed integrally with each other.

From the viewpoint of the adhesion and the crystallinity, the contact resistance is generated between the plug PG1a and the wiring NL1a of the first embodiment shown in FIG. 1 and between the plug PG1b and the wiring NL1b of the first embodiment. On the other hand, since the conductor film PCF is integrally formed in the wirings NL5a and NL5b of the second embodiment shown in FIG. 25, the contact resistance is not generated unlike the first embodiment. Therefore, the second embodiment is more advantageous than the first embodiment in that it is possible to reduce the resistance between the wiring layers (insulating layer IL1 and insulating layer IL2).

In addition, as shown in FIGS. 26 to 30, the wirings NL5a and NL5b and the plugs PG2c, PG2d, and PG2e included in the insulating layer IL1 and the wirings NL5a, NL5b, and NL5c included in the insulating layer IL2 are formed in the single process in the second embodiment. Namely, the contact to the MOSFET in the insulating layer IL1 and the wiring formation in the insulating layer IL2 can be performed in the single process. As described above, from the viewpoint of the cost reduction by the reduction in the number of processes, the second embodiment is more advantageous than the first embodiment.

Meanwhile, as shown in FIG. 26, since it is necessary to bury the barrier conductor film B2a in the thorough hole SH1 in the second embodiment, the MOCVD method with better burying property as compared with the PVD method is used as the method of forming the barrier conductor film B2a. In addition, as shown in FIG. 27, since it is necessary to bury the conductor film PCF in the through hole SH1, the CVD method with better burying property as compared with the PVD method is used as the method of forming the conductor film PCF.

Although only the materials to be deposited are present in the PVD method, various chemical species are generated in vapor phase in the CVD method, and thus there is fear that not only the chemical species desired as the precursor but also the impurities are mixed into the film and the film quality is lowered. Therefore, from the viewpoint of forming a barrier conductor film and a conductor film of good film quality, the first embodiment is more advantageous than the second embodiment.

Note that, in the second embodiment, the case where the barrier conductor film B2b is formed on the conductor film PCF in each of the wirings NL5a, NL5b, and NL5c as shown in FIG. 25 has been described, but it is not always necessary to form the barrier conductor film B2b (see first modification described above). In this case, the wiring DLa is electrically connected to the wiring NL5c by penetrating the barrier insulating film BI1 to be in contact with the conductor film PCF.

In addition, the manufacturing method in this case does not include the process of forming the barrier conductor film B2b on the conductor film PCF shown in FIG. 27. Therefore, a photoresist film is formed on the conductor film PCF, and the photoresist film is patterned to form the photoresist films PR4a, PR4b, and PR4c (see FIG. 28). This point is the difference from the second embodiment described above, the other process is the same as that of the present embodiment described above, and thus the repetitive description is omitted.

The advantage in the case where the barrier conductor film B2b is not formed as described above is the same as that described in the first modification. Namely, as described above, tantalum nitride constituting the barrier conductor film B1b has the bulk electrical resistivity larger than those of copper and the post copper material. Therefore, the wiring resistance of the wirings including no barrier conductor film B2b is smaller than that of the wirings NL5a, NL5b, and NL5c including the barrier conductor film B2b. As a result, the case where the barrier conductor film B2b is not formed is more advantageous than the semiconductor device SD2 according to the second embodiment in that it is possible to reduce the resistance of the wiring having small wiring width among the wirings formed in the same wiring layer.

Meanwhile, as described above, it is possible to prevent the upper surface of the conductor film PCF from being damaged in the process of removing the photoresist films PR4a, PR4b, and PR4c by the presence of the barrier conductor film B2b in the second embodiment described above. Therefore, the semiconductor device SD2 according to the second embodiment is more advantageous in this point than the case where the barrier conductor film B2b is not formed.

### Third Embodiment

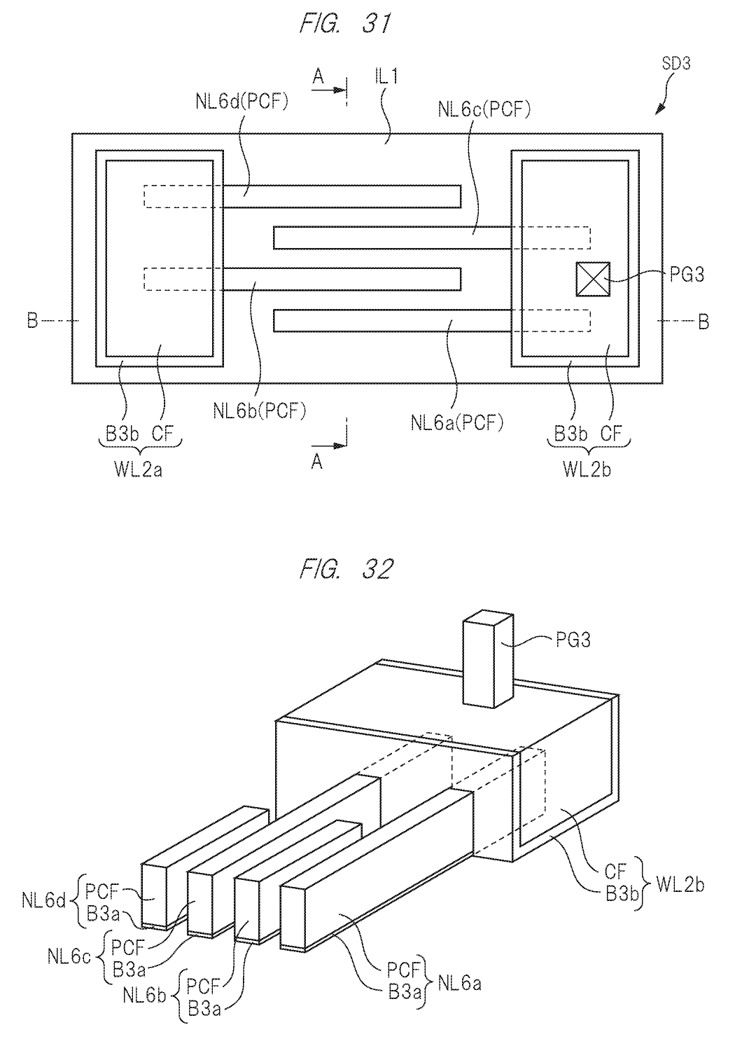

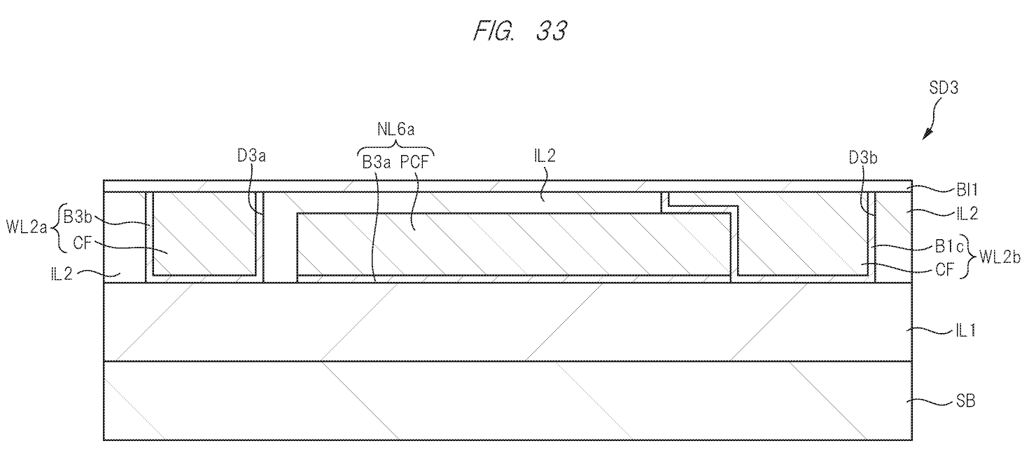

A configuration of a semiconductor device SD3 according to a third embodiment will be described with reference to FIGS. 31 to 33. FIG. 31 is a plan view of the semiconductor device SD3 according to the third embodiment, FIG. 32 is a view seen along a direction of arrows A-A in FIG. 31, and FIG. 33 is a cross-sectional view showing a structure taken along a line B-B in FIG. 31. Note that the structure below the insulating layer IL1, the insulating layer IL2, the barrier insulating film BI1, and the structure above the barrier insulating film BI1 (other than plug PG3) shown in FIG. 33 are omitted in FIG. 32 for easy understanding of the structure of the semiconductor device SD3.

As shown in FIG. 33, the semiconductor device SD3 according to the third embodiment includes the substrate SB and the insulating layer IL1 formed on the substrate SB. Also, as shown in FIGS. 31 to 33, wirings NL6a, NL6b, NL6c, and NL6d are formed on the insulating layer IL1. In addition, wirings WL2a and WL2b are formed on the insulating layer ILL A width of each of the wirings NL6a, NL6b, NL6c, and NL6d is smaller than a width of each of the wirings WL2a and WL2b. Namely, the wirings NL6a, NL6b, NL6c, and NL6d and the wirings WL2a and WL2b having different wirings widths are formed in the same layer (same wiring layer). Further, the wirings NL6a and NL6c are electrically connected to the wiring WL2b. The wirings NL6b and NL6d are electrically connected to the wiring WL2a.

As shown in FIGS. 32 and 33, the wirings NL6a, NL6b, NL6c, and NL6d are each composed of a stacked film of a barrier conductor film B3a and the conductor film PCF. Note that the barrier conductor film B3a is not formed on side surfaces and upper surfaces of the wirings NL6a, NL6b, NL6c, and NL6d. Also, as shown in FIG. 33, the wirings WL2a and WL2b are buried in wiring trenches D3a and D3b formed in the insulating layer IL2, respectively. The wirings WL2a and WL2b are damascene wirings (damascene buried wirings) formed by the damascene method. The wirings WL2a and WL2b are each composed of a stacked film of a barrier conductor film B3b and the conductor film PCF. The barrier conductor films B3a and B3b are each composed of, for example, a tantalum nitride (TaN) film, a titanium nitride (TiN) film, or a stacked film of a tantalum nitride (TaN) film and a tantalum (Ta) film.

Also, as shown in FIG. 33, the barrier insulating film BI1 is formed on the insulating layer IL2. Thus, upper surfaces of the wirings WL2a and WL2b are covered with the barrier insulating film BI1.

In addition, as shown in FIG. 31, a plug PG3 is formed on the barrier insulating film BI1 formed on the wiring WL2b. The plug PG3 is composed of, for example, a barrier conductor film and a main conductor film. The barrier conductor film is made of, for example, a titanium (Ti) film, a tantalum (Ta) film, a titanium nitride (TiN) film, or a tantalum nitride (TaN) film. The main conductor film is made of, for example, tungsten (W). The plug PG3 penetrates the barrier insulating film BI1 to be in contact with the conductor film CF so as to be electrically connected to the wiring WL2b and the structure formed over the barrier insulating film BI1 (not shown).

Though not shown, in the semiconductor device SD3 according to the third embodiment, a MOSFET is formed in a region (not shown) of the substrate SB and the insulating layer IL1 as in the semiconductor device SD1 according to the first embodiment described above. Therefore, for example, the wiring NL6c is arranged on the source region of the MOSFET, and the wiring NL6d is arranged on the drain region of the MOSFET.

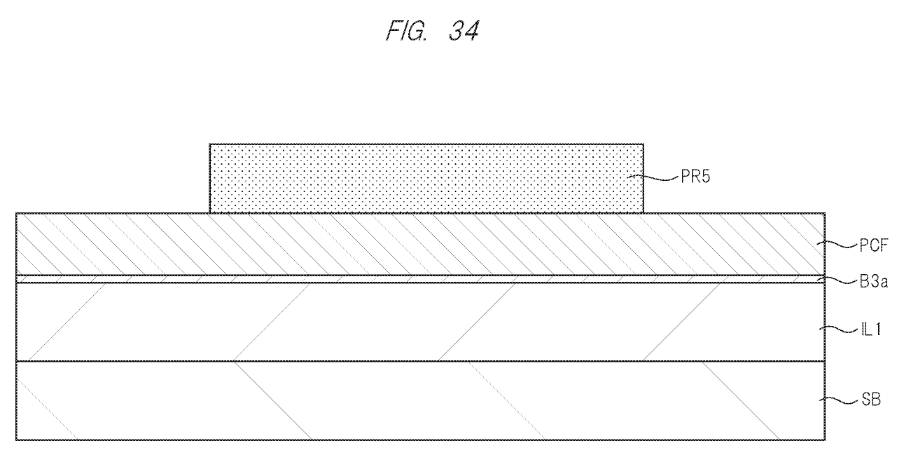

Next, a manufacturing method of the semiconductor device SD3 according to the third embodiment will be described in order of processes with reference to FIGS. 34 to 41. FIGS. 34 to 41 are cross-sectional views of a principal part in the manufacturing process of the semiconductor device SD3 according to the third embodiment, and each show the cross-section corresponding to FIG. 33 shown above.

In the manufacturing method of the semiconductor device SD3 according to the third embodiment shown in FIG. 33, the process from the preparation of the substrate SB to the formation of the conductor film PCF (see FIGS. 2 to 6) is almost the same as that of the manufacturing method of the semiconductor device SD1 according to the first embodiment except for that the MOSFET and the silicide SC are not shown and the barrier conductor film B1a is changed to the barrier conductor film B3a.

Thereafter, as shown in FIG. 34, a photoresist film is formed on the conductor film PCF, and the photoresist film is patterned to form a photoresist film PR5.

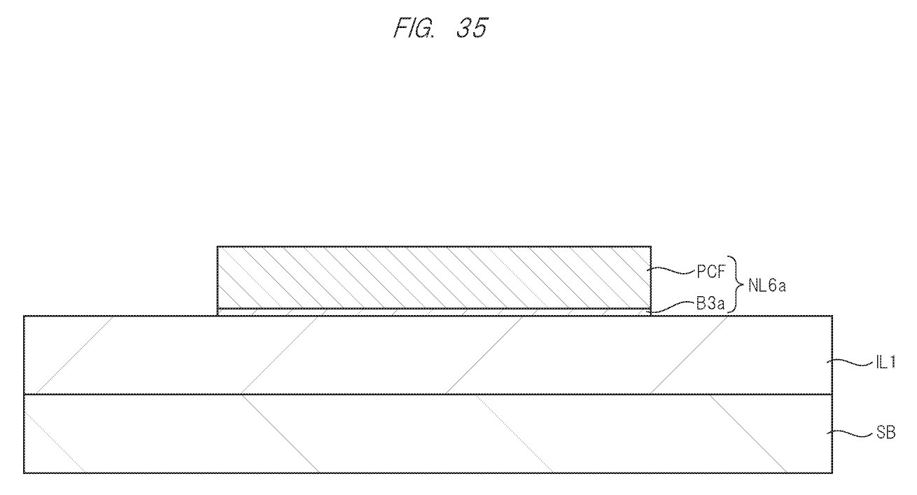

Next, the conductor film PCF and the barrier conductor film B3a are patterned by the dry etching using fluorine gas at about 200 to 300° C. with using the photoresist film PR5 as a mask. Subsequently, the photoresist film PR5 is removed by the etching using organic solvent containing organic acid or the oxygen plasma asking. Thus, as shown in FIG. 35, the wiring NL6a composed of the stacked film of the barrier conductor film B3a and the conductor film PCF is formed on the insulating layer IL1. Though not shown, in this process, the wirings NL6b, NL6c, and NL6d each composed of the stacked film of the barrier conductor film B3a and the conductor film PCF are also formed on the insulating layer IL1 simultaneously with the wiring NL6a.

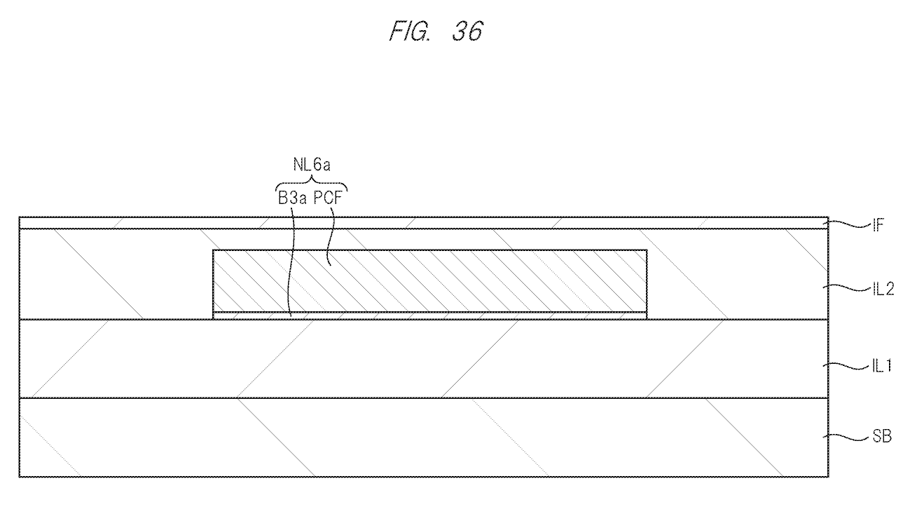

Next, as shown in FIG. 36, for example, MSQ is coated to 100 to 200 nm, and then sintered at 400° C. for 30 minutes to form the insulating layer IL2 on the insulating layer IL1 so as to cover the wiring NL6a. Though not shown, in this process, the wirings NL6b, NL6c, and NL6d are also covered with the insulating layer IL2. Subsequently, the insulating layer IL2 is planarized by the CMP method such that the insulating layer IL2 has a thickness of 60 to 90 nm. Further, the insulating film IF made of, for example, a silicon oxide film is formed on the insulating layer IL2 by, for example, the PECVD method.

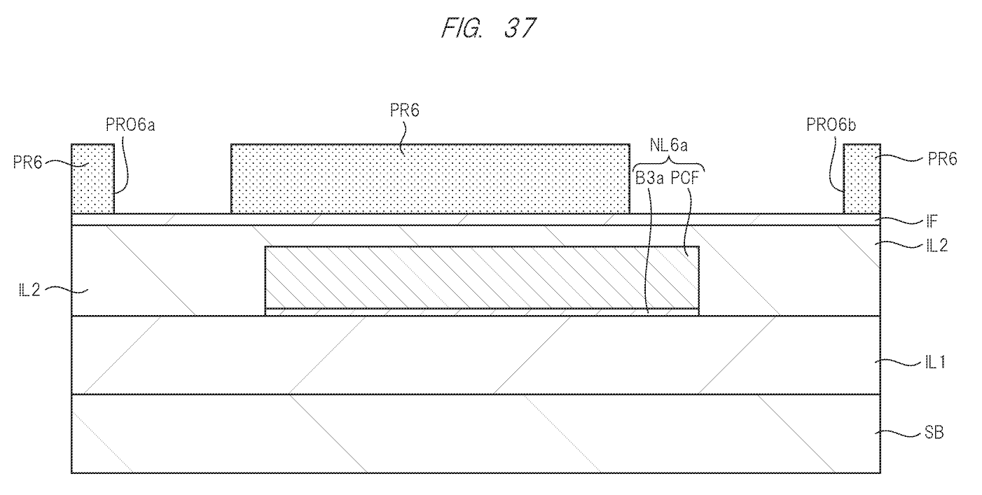

Next, as shown in FIG. 37, a photoresist film PR6 is formed on the insulating film IF. Then, the photoresist film PR6 is patterned to form openings PRO6a and PRO6b in the photoresist film PR6.

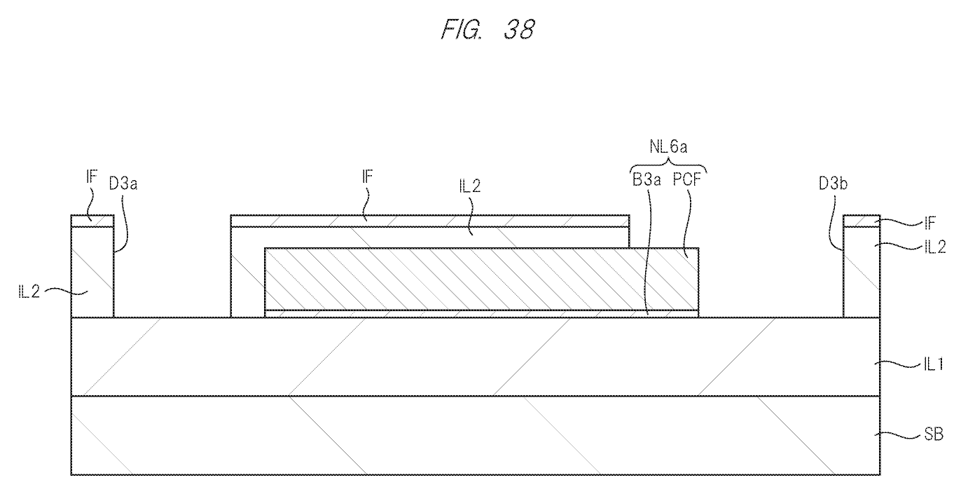

Next, the insulating film IF and the insulating layer IL2 are subjected to dry etching by the RIE method using fluorocarbon gas through the openings PRO6a and PRO6b of the photoresist film PR6 with using the photoresist film PR6 as a mask, thereby patterning the insulating layer IL2. Thus, as shown in FIG. 38, the wiring trenches D3a and D3b are formed in the insulating layer IL2. The wiring trench D3b is formed such that apart of the upper surface of the insulating layer IL1 including an upper surface and a side surface of the wiring NL6a is exposed. Note that, in this process, the barrier conductor film B3a and the conductor film PCF constituting the wiring NL6a are not etched. Also, though not shown, the wiring trench D3a is formed such that a part of the upper surface of the insulating layer IL1 including upper surfaces and side surfaces of the wirings NL6b and NL6d is exposed. In addition, an upper surface and a side surface of the wiring NL6c are also exposed in the wiring trench D3b. Subsequently, the photoresist film PR6 is removed by the etching using organic solvent containing organic acid or the oxygen asking.

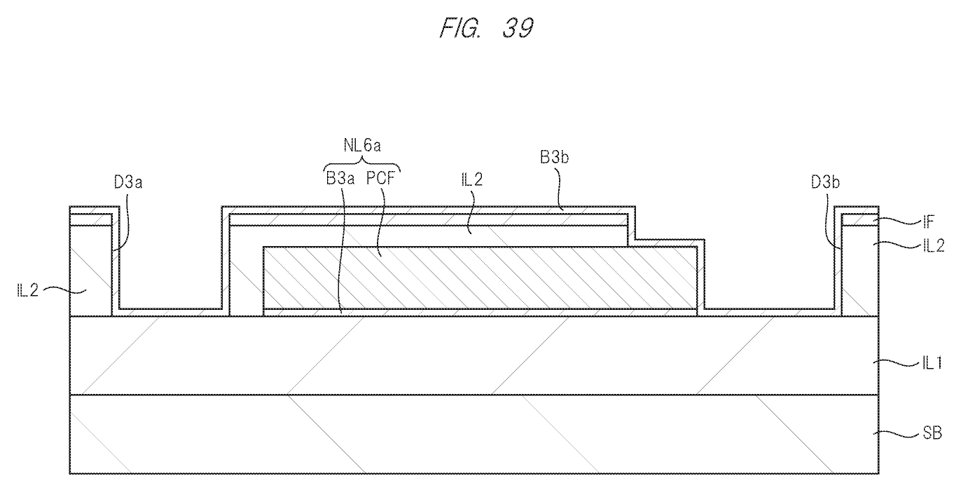

Next, as shown in FIG. 39, the barrier conductor film B3b made of, for example, tantalum nitride is formed on the insulating layer IL2 by, for example, the PVD method. Thus, the barrier conductor film B3b is formed on the bottoms and side walls of the wiring trenches D3a and D3b. At this time, the barrier conductor film B3b is formed also on the upper surface and side surface of the wiring NL6a exposed in the wiring trench D3b. In addition, though not shown, the barrier conductor film B3b is formed also on the upper surface and side surface of the wiring NL6c exposed in the wiring trench D3b and on the upper surfaces and side surfaces of the wirings NL6b and NL6d exposed in the wiring trench D3a.

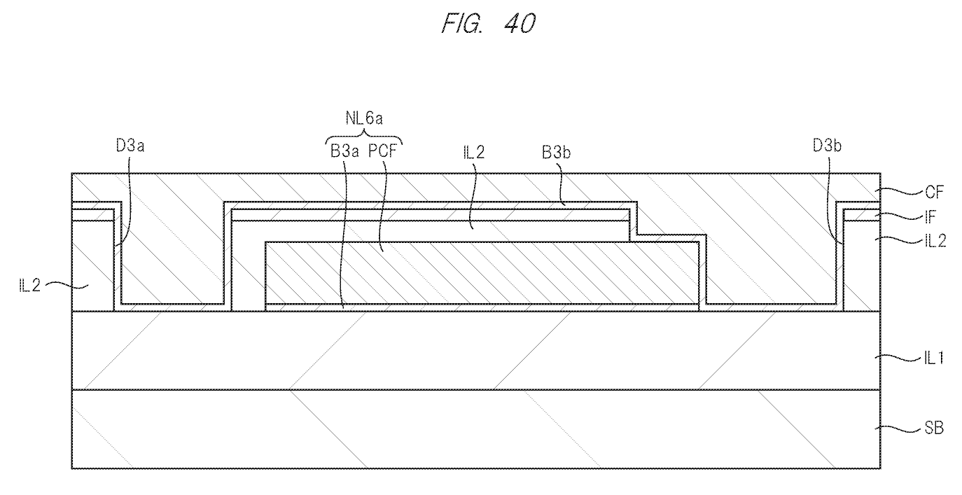

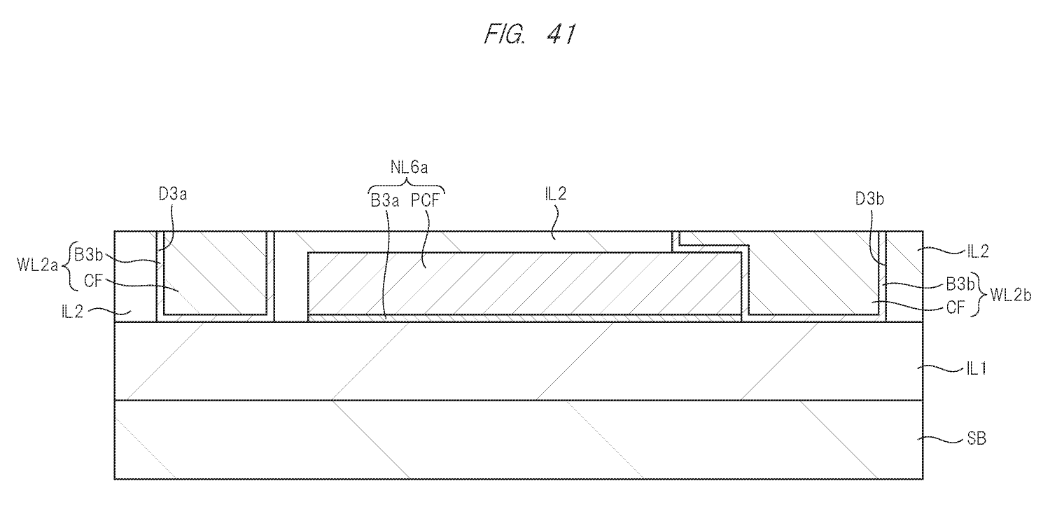

Next, though not shown, a seed film made of copper having a thickness of 30 to 50 nm is formed on the barrier conductor film B3b by, for example, the PVD method. Then, as shown in FIG. 40, the conductor film CF made of copper having a thickness of 100 to 200 nm is formed on the seed film (not shown) by the electroplating method. Thus, the wiring trenches D3a and D3b are filled with the conductor film CF. Thereafter, the heat treatment is performed at about 450° C. for 30 minutes.

Next, as shown in FIG. 41, the barrier conductor film B3b and the conductor film CF outside the wiring trenches D3a and D3b are removed by the CMP method. Thus, the barrier conductor film B3b and the conductor film CF are left in the wiring trenches D3a and D3b. As a result, the wirings WL2a and WL2b each composed of the barrier conductor film B3b and the conductor film CF are formed on the insulating layer IL1. Note that the insulating film IF is also removed together with the barrier conductor film B3b and the conductor film CF outside the wiring trenches D3a and D3b by the CMP method in order to reduce the capacitance between wirings.

Next, as shown in FIG. 33, the barrier insulating film BI1 is formed on the insulating layer IL2 by, for example, the PECVD method. Thus, the wirings WL2a and WL2b are covered with the barrier insulating film BI1 made of a silicon carbonitride (SiCN) film.

Thereafter, through the process of forming other wirings including the plug PG3 (see FIGS. 31 and 32) on the barrier insulating film BI1, the process of forming a pad electrode and a passivation film in the further upper layer, and the process of dicing the semiconductor substrate SB into a plurality of chips, the semiconductor device SD3 according to the third embodiment is completed.

As shown in FIGS. 31 to 33, in the semiconductor device SD3 according to the third embodiment, among the wirings NL6a, NL6b, NL6c, and NL6d and the wirings WL2a and WL2b formed in the same wiring layer, the wirings NL6a, NL6b, NL6c, and NL6d having small wiring width are each composed of a stacked film of the barrier conductor film B3a and the conductor film PCF made of the post copper material. Also, the barrier conductor film B3a is not formed on the side surfaces of the wirings NL6a, NL6b, NL6c, and NL6d. In addition, among the wirings NL6a, NL6b, NL6c, and NL6d and the wirings WL2a and WL2b formed in the same wiring layer, the wirings WL2a and WL2b having large wiring width are each composed of the barrier conductor film B3b and the conductor film CF made of copper. Further, the wirings NL6a and NL6c are electrically connected to the wiring WL2b. The wirings NL6b and NL6d are electrically connected to the wiring WL2a.

Namely, in the semiconductor device SD3 according to the third embodiment, as in the first embodiment, it is possible not only to reduce the resistance of the wirings having small wiring width and the resistance of the wirings having large wiring width formed in the same wiring layer, but also to electrically connect the wirings having small wiring width and the wirings having large wiring width to each other. Accordingly, it is possible to improve the degree of freedom in the wiring layout in the semiconductor device.

Also, in the manufacturing method of the semiconductor device SD3 according to the third embodiment, the barrier conductor film B3b is formed also on the upper surface and side surface of the wiring NL6a exposed in the wiring trench D3b in the process of forming the wirings WL2a and WL2b shown in FIGS. 37 to 41. In addition, though not shown, the barrier conductor film B3b is formed also on the upper surface and side surface of the wiring NL6c exposed in the wiring trench D3b and on the upper surfaces and side surfaces of the wirings NL6b and NL6d exposed in the wiring trench D3a. Thereafter, the conductor film CF is buried on the barrier conductor film B3b in the wiring trenches D3a and D3b, thereby forming the wirings WL2a and WL2b. As a result, in the process of forming the wirings WL2a and WL2b shown in FIGS. 37 to 41, the wirings NL6a and NL6c are electrically connected to the wiring WL2b, and the wirings NL6b and NL6d are electrically connected to the wiring WL2a.

As described above, in the third embodiment, the process of electrically connecting the wirings having small wiring width and the wirings having large wiring width to each other is unnecessary, and it is thus possible to reduce the manufacturing cost of the semiconductor device.

Note that, in the third embodiment, the case where the wirings NL6a, NL6b, NL6c, and NL6d are each composed of a stacked film of the barrier conductor film B3a and the conductor film PCF made of the post copper material has been described, but the wirings are not limited to this. For example, the barrier conductor film may be formed on the conductor film PCF as in the first embodiment and the second modification described above, and the barrier conductor film may not be formed below the conductor film PCF as in the second modification and the third modification described above.

In the foregoing, the invention made by the inventor of the present invention has been concretely described based on the embodiments. However, it is needless to say that the present invention is not limited to the foregoing embodiments and various modifications can be made within the scope of the present invention.

In addition, what corresponds to the contents described in the above embodiments or a part thereof will be described below.

### APPENDIX 1

A manufacturing method of a semiconductor device comprising the steps of:

(a) preparing a substrate;

(b) forming a first insulating film on the substrate;

(c) after the step (b), forming a first barrier conductor film on the first insulating film;

(d) after the step (c), patterning the first barrier conductor film;

(e) forming a first conductor film on the patterned first barrier conductor film by selective CVD method, thereby forming a first wiring composed of a stacked film of the first barrier conductor film and the first conductor film on the first barrier conductor film;

(f) after the step (e), forming a second insulating film so as to cover the first wiring;

(g) after the step (f), forming a first trench in the second insulating film;

(h) after the step (g), forming a second barrier conductor film and a second conductor film in sequence on the second insulating film so as to fill the first trench; and

(i) after the step (h), removing the second conductor film and the second barrier conductor film outside the first trench, thereby forming a second wiring composed of a stacked film of the second barrier conductor film and the second conductor film on the second barrier conductor film in the first trench,

wherein the first wiring and the second wiring constitute the same wiring layer,

a wiring width of the first wiring is smaller than a wiring width of the second wiring,

the first conductor film is made of a material mainly containing a metal element whose mean free path of electrons is smaller than that of copper, and

the second conductor film is made of copper.

### APPENDIX 2

The manufacturing method of the semiconductor device according to the Appendix 1,

wherein the first conductor film is made of any one of cobalt, ruthenium, tungsten, molybdenum, aluminum, cobalt aluminum, nickel, rhodium, iridium, and zinc.

### APPENDIX 3

The manufacturing method of the semiconductor device according to the Appendix 1,

wherein, in the step (d), the first barrier conductor film is patterned by anisotropically etching the first barrier conductor film with using a photoresist film as a mask.

### APPENDIX 4

The manufacturing method of the semiconductor device according to the Appendix 1,

wherein the first insulating film is made of a material having a relative permittivity lower than that of silicon oxide.

### APPENDIX 5

The manufacturing method of the semiconductor device according to the Appendix 1,

wherein the first barrier conductor film and the second barrier conductor film are each made of a tantalum nitride film.

What is claimed is:

1. A semiconductor device comprising:
a substrate;
a plurality of wiring layers formed on the substrate; and
a first wiring and a second wiring formed in a first wiring layer among the plurality of wiring layers,
wherein a wiring width of the first wiring is smaller than a wiring width of the second wiring,
the first wiring is composed of any one of a first conductor film, a stacked film of a first barrier conductor film and the first conductor film, a stacked film of the first conductor film and a second barrier conductor film, and a stacked film of the first barrier conductor film, the first conductor film, and the second barrier conductor film,
the second wiring is composed of a stacked film of a third barrier conductor film and a second conductor film,
the first conductor film is made of a material mainly containing a metal element whose mean free path of electrons is smaller than that of copper, and
the second conductor film is made of copper.

2. The semiconductor device according to claim 1,
wherein the first conductor film is made of any one of cobalt, ruthenium, tungsten, molybdenum, aluminum, cobalt aluminum, nickel, rhodium, iridium, and zinc.

3. The semiconductor device according to claim 1,
wherein the second wiring is buried in a first trench formed in a first insulating film constituting the first wiring layer.

4. The semiconductor device according to claim 1, further comprising:
a third wiring formed in a second wiring layer among the plurality of wiring layers,
wherein the second wiring layer is a wiring layer immediately above the first wiring layer, and
the third wiring is a dual damascene wiring.

5. The semiconductor device according to claim 1,
wherein the first wiring is composed of a stacked film of the first barrier conductor film, the first conductor film on the first barrier conductor film, and the second barrier conductor film on the first conductor film.

6. The semiconductor device according to claim 1,
wherein the first wiring is composed of a stacked film of the first barrier conductor film and the first conductor film on the first barrier conductor film.

7. The semiconductor device according to claim 1,
wherein the first wiring is composed of a stacked film of the first conductor film and the second barrier conductor film on the first conductor film.

8. The semiconductor device according to claim 1,
wherein the first barrier conductor film and the second barrier conductor film are not formed on a side surface of the first wiring.

9. The semiconductor device according to claim 1,
wherein the first wiring is composed of the first conductor film.

10. The semiconductor device according to claim 1,
wherein a semiconductor element is formed on the substrate,
the semiconductor element includes:
a source region and a drain region formed in the substrate; and
a gate electrode formed via a gate insulating film on the substrate between the source region and the drain region,
the first wiring layer is a lowermost wiring layer among the plurality of wiring layers,
a second insulating film and a first plug and a second plug buried in the second insulating film are provided below the first wiring layer,
the first plug is electrically connected to the source region,
the second plug is electrically connected to the drain region, and
the first wiring includes a source wiring electrically connected to the first plug and a drain wiring electrically connected to the second plug.

11. The semiconductor device according to claim 10,
wherein the source wiring and the first plug are formed integrally with each other, and
the drain wiring and the second plug are formed integrally with each other.

12. The semiconductor device according to claim 3,
wherein the first insulating film is formed so as to cover the first wiring,
the first trench is formed so as to expose the first wiring in the first trench, and
the second wiring is electrically connected to the first wiring in the first trench.

13. A manufacturing method of a semiconductor device comprising the steps of:
(a) preparing a substrate;
(b) forming a first insulating film on the substrate;
(c) after the step (b), forming a first conductor film on the first insulating film;
(d) after the step (c), forming a first wiring by anisotropically etching the first conductor film with using a photoresist film as a mask;
(e) after the step (d), forming a second insulating film so as to cover the first wiring;
(f) after the step (e), forming a first trench in the second insulating film;
(g) after the step (f), forming a first barrier conductor film and a second conductor film in sequence on the second insulating film so as to fill the first trench; and
(h) after the step (g), removing the second conductor film and the first barrier conductor film outside the first trench, thereby forming a second wiring composed of a stacked film of the first barrier conductor film and the second conductor film on the first barrier conductor film in the first trench,
wherein the first wiring and the second wiring constitute the same wiring layer,
a wiring width of the first wiring is smaller than a wiring width of the second wiring,
the first conductor film is made of a material mainly containing a metal element whose mean free path of electrons is smaller than that of copper, and
the second conductor film is made of copper.

14. The manufacturing method of the semiconductor device according to claim 13, further comprising the step of:
after the step (b) and before the step (c),
(i) forming a second barrier conductor film on the first insulating film,
wherein, in the step (c), the first conductor film is formed on the second barrier conductor film, and
in the step (d), the first conductor film and the second barrier conductor film are anisotropically etched with using the photoresist film as a mask, thereby forming the first wiring composed of a stacked film of the second barrier conductor film and the first conductor film on the second barrier conductor film.

15. The manufacturing method of the semiconductor device according to claim 13, further comprising the step of:
after the step (c) and before the step (d),
(j) forming a third barrier conductor film on the first conductor film,
wherein, in the step (d), the third barrier conductor film and the first conductor film are anisotropically etched with using the photoresist film as a mask, thereby forming the first wiring composed of a stacked film of the first conductor film and the third barrier conductor film on the first conductor film.

16. The manufacturing method of the semiconductor device according to claim 13, further comprising the steps of:
after the step (b) and before the step (c),
(i) forming a second barrier conductor film on the first insulating film; and
after the step (c) and before the step (d),
(j) forming a third barrier conductor film on the first conductor film,
wherein, in the step (c), the first conductor film is formed on the second barrier conductor film, and
in the step (d), the third barrier conductor film, the first conductor film, and the second barrier conductor film are anisotropically etched with using the photoresist film as a mask, thereby forming the first wiring composed of a stacked film of the second barrier conductor film, the first conductor film on the second barrier conductor film, and the third barrier conductor film on the first conductor film.

17. The manufacturing method of the semiconductor device according to claim 13,
wherein, in the step (f), the first wiring is exposed in the first trench,
in the step (g), the first barrier conductor film and the second conductor film are formed also on the first wiring in the first trench, and
in the step (h), the second wiring is electrically connected to the first wiring.

18. The manufacturing method of the semiconductor device according to claim 13, further comprising the steps of:
after the step (a) and before the step (b),
(k) forming a gate electrode on the substrate via a gate insulating film;
(l) after the step (k), forming a source region and a drain region in the substrate;
after the step (b) and before the step (c),
(m) forming a first opening reaching the source region and a second opening reaching the drain region in the first insulating film; and
(n) forming a first plug in the first opening and forming a second plug in the second opening,
wherein, in the step (c), the first conductor film is formed on the first insulating film in which the first plug and the second plug are buried,
the first plug is electrically connected to the source region,
the second plug is electrically connected to the drain region, and
the first wiring includes a source wiring electrically connected to the first plug and a drain wiring electrically connected to the second plug.

19. The manufacturing method of the semiconductor device according to claim 13, further comprising the steps of:
after the step (a) and before the step (b),
(k) forming a gate electrode on the substrate via a gate insulating film;
(l) after the step (k), forming a source region and a drain region in the substrate;
after the step (b) and before the step (c),
(m) forming a first opening reaching the source region and a second opening reaching the drain region in the first insulating film; and
(n) after the step (m), forming a second barrier conductor film on the first insulating film and in the first opening and the second opening,
wherein, in the step (c), the first conductor film is formed on the first insulating film so as to fill the first opening and the second opening,
a first plug is formed in the first opening and a second plug is formed in the second opening,
in the step (d), the first conductor film and the second barrier conductor film are anisotropically etched with using the photoresist film as a mask, thereby forming the first wiring composed of a stacked film of the second barrier conductor film and the first conductor film on the second barrier conductor film,
the first plug is electrically connected to the source region,
the second plug is electrically connected to the drain region,
the first wiring includes a source wiring electrically connected to the first plug and a drain wiring electrically connected to the second plug,
in the step (d), the source wiring is formed integrally with the first plug, and
the drain wiring is formed integrally with the second plug.

20. The manufacturing method of the semiconductor device according to claim 13,
wherein the first conductor film is made of any one of cobalt, ruthenium, tungsten, molybdenum, aluminum, cobalt aluminum, nickel, rhodium, iridium, and zinc.
